(19) United States
(12) Patent Application Publication
(10) Pub. No.: US 2025/0204220 A1
(43) Pub. Date: Jun. 19, 2025

(54) DISPLAY DEVICE

(71) Applicant: LG Display Co., Ltd., Seoul (KR)

(72) Inventors: YoungHoon SON, Gimpo-si (KR); Hyeju CHOI, Iksan-si (KR)

(73) Assignee: LG Display Co., Ltd., Seoul (KR)

(21) Appl. No.: 18/907,839

(22) Filed: Oct. 7, 2024

(30) Foreign Application Priority Data
Dec. 15, 2023 (KR) 10-2023-0182785

(51) Int. Cl. H10K 59/80; H10K 59/131; H10K 102/00

(52) U.S. Cl. CPC H10K 59/873; H10K 59/131; H10K 2102/311

(57) ABSTRACT

A display device may include a stretchable lower substrate, a plurality of plate patterns disposed on the stretchable lower substrate and spaced apart from one another, a plurality of light-emitting elements disposed on the plurality of plate patterns, a plurality of stretchable connection lines disposed between the plurality of plate patterns, a first encapsulation layer configured to cover the plurality of light-emitting elements, and a second encapsulation layer configured to cover the plurality of stretchable connection lines. Therefore, the second encapsulation layer may be formed to cover the plurality of stretchable connection lines, which may protect the plurality of stretchable connection lines from moisture and oxygen and improve the reliability of the plurality of stretchable connection lines.

### CROSS-REFERENCE TO RELATED APPLICATIONS

This application claims the benefit of and priority to Korean Patent Application No. 10-2023-0182785 filed on Dec. 15, 2023, in the Korean Intellectual Property Office, the entire contents of which are incorporated herein by reference for all purposes.

### BACKGROUND

### 1. Technical Field

The present disclosure relates to a display device, and particularly to, for example, without limitation, a stretchable display device having a stretchable line with improved reliability.

### 2. Description of the Related Art

A display field for visually expressing electrical information signals has been rapidly developed as the information age has come in earnest. Therefore, various display devices, which are thin in thickness and light in weight and have excellent performances such as low power consumption, have been developed. Examples of the display devices may include a liquid crystal display (LCD) device, an organic light-emitting display (OLED) device, and the like.

The range of application of the display devices is diversified from the monitor of the computer and the TV set to personal mobile devices, and studies are being conducted on the display devices having wide display areas and having reduced volumes and weights.

In addition, recently, display devices have been made by forming display parts, lines, and the like on substrates made of flexible plastic materials and having flexibility. The display devices are manufactured to be stretchable in particular directions and variously changeable in shapes, and thus attract attention as next-generation display devices.

The description of the related art should not be assumed to be prior art merely because it is mentioned in or associated with this section. The description of the related art includes information that describes one or more aspects of the subject technology, and the description in this section does not limit the invention.

### SUMMARY

An aspect to be achieved by the present disclosure is to provide a display device capable of protecting a stretchable connection line from moisture and oxygen.

Another aspect to be achieved by the present disclosure is to provide a display device capable of minimizing damage to a stretchable connection line by protecting the connection line from moisture and oxygen.

Still another aspect to be achieved by the present disclosure is to provide a display device in which a line encapsulation layer for sealing a connection line is formed together with a light-emitting element and an encapsulation layer for sealing the light-emitting element.

Yet another aspect to be achieved by the present disclosure is to provide a display device in which a lower substrate may be used as an encapsulation layer of a connection line.

Still yet another aspect to be achieved by the present disclosure is to provide a display device in which a fluorine-based residual film is formed on a front surface to minimize the penetration of moisture.

Aspects of the present disclosure are not limited to the above-mentioned aspects, and other aspects, which are not mentioned above, can be clearly understood by those skilled in the art from the following descriptions.

In order to achieve the above-mentioned aspects, one or more example embodiments of the present disclosure provide a display device including a stretchable lower substrate, a plurality of plate patterns disposed on the stretchable lower substrate and spaced apart from one another, a plurality of light-emitting elements disposed on the plurality of plate patterns, a plurality of stretchable connection lines disposed between the plurality of plate patterns, a first encapsulation layer configured to cover the plurality of light-emitting elements, and a second encapsulation layer configured to cover the plurality of stretchable connection lines. Therefore, the second encapsulation layer may be formed to cover the plurality of stretchable connection lines, which may protect the plurality of stretchable connection lines from moisture and oxygen and improve the reliability of the plurality of stretchable connection lines.

Other detailed matters of the example embodiments are included in the detailed description and the drawings.

According to one or more aspects of the present disclosure, it is possible to protect the stretchable connection line from moisture and oxygen.

According to one or more aspects of the present disclosure, it is possible to seal and protect the stretchable connection line so that the connection line is not damaged by moisture, oxygen, and the like.

According to one or more aspects of the present disclosure, it is possible to easily form the line encapsulation layer, which seals the connection line, by forming the line encapsulation layer together during the process of manufacturing some components of the pixel.

According to one or more aspects of the present disclosure, it is possible to form the line encapsulation layer, which seals the connection line, together with the light-emitting element and the encapsulation layer configured to seal the light-emitting element.

According to one or more aspects of the present disclosure, the lower substrate is used as the encapsulation layer of the connection line, which may simplify the structure of the display device.

According to one or more aspects of the present disclosure, the fluorine-based residual film is formed on the front surface of the lower substrate, which may delay the penetration of moisture into the light-emitting element, the connection line, or the like.

The effects according to the present disclosure are not limited to the contents illustrated above, and more various effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a top plan view of a display device according to an example embodiment of the present disclosure;

FIG. 2 is an enlarged top plan view of a display area of the display device according to the example embodiment of the present disclosure;

FIG. 3 is a cross-sectional view taken along line III-III′ in FIG. 2;

FIG. 4 is a cross-sectional view for explaining a process of manufacturing a second encapsulation layer of the display device according to the example embodiment of the present disclosure;

FIG. 5 is a cross-sectional view of a display device according to another example embodiment of the present disclosure;

FIG. 6 is a cross-sectional view for explaining a process of manufacturing a second encapsulation layer of the display device according to another example embodiment of the present disclosure;

FIG. 7 is a cross-sectional view of a display device according to still another example embodiment of the present disclosure;

FIG. 8 is a cross-sectional view of a display device according to yet another example embodiment of the present disclosure;

FIG. 9 is a cross-sectional view of a display device according to still yet another example embodiment of the present disclosure;

FIG. 10 is a cross-sectional view of a display device according to a further example embodiment of the present disclosure;

FIG. 11 is a cross-sectional view of a display device according to another further example embodiment of the present disclosure; and

FIG. 12 is a cross-sectional view of a display device according to still another further example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, section, member, part, region, area, portion, or the like) “is engaged” with another element may be understood, for example, as that the element may be either directly or indirectly engaged with the another element. The term “is engaged” or similar expressions may refer to a term such as “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, at least a portion (or a part) of an element can represent (i) a portion (or a part) of the element, (ii) one or more portions (or parts) of the element, or (iii) the element, or all parts of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

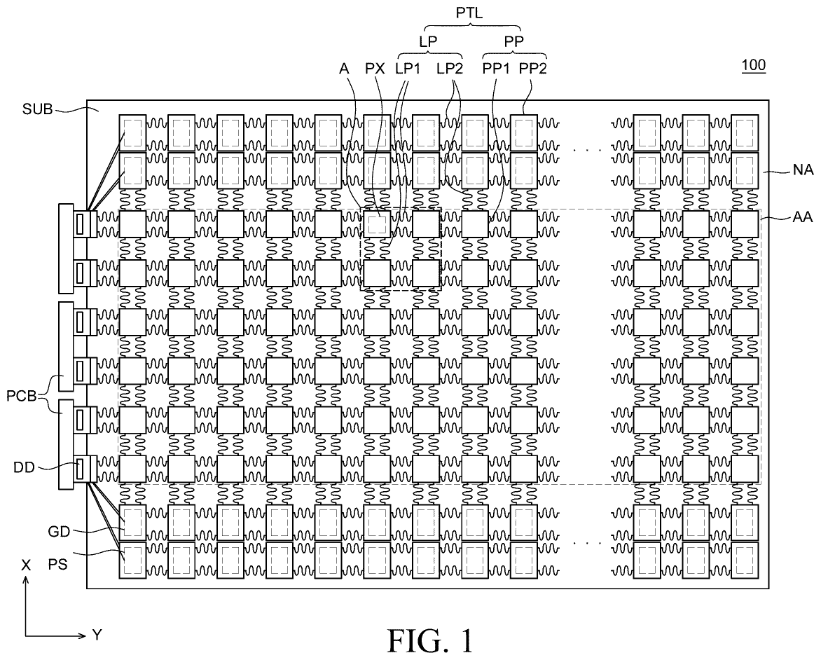

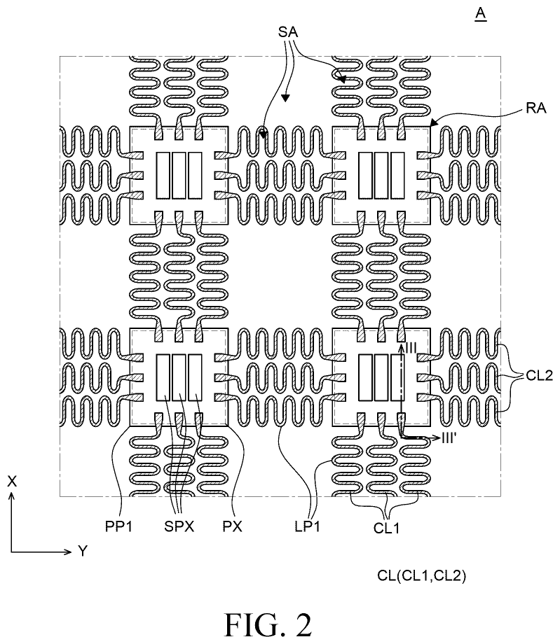

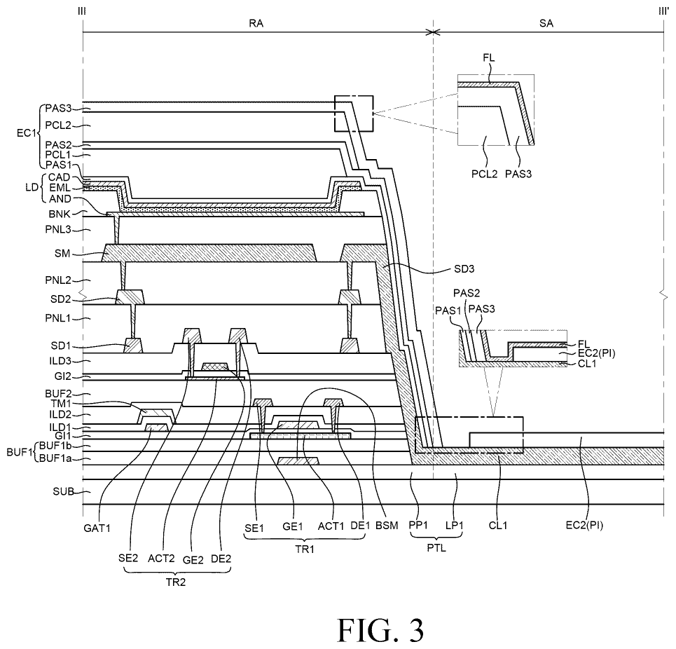

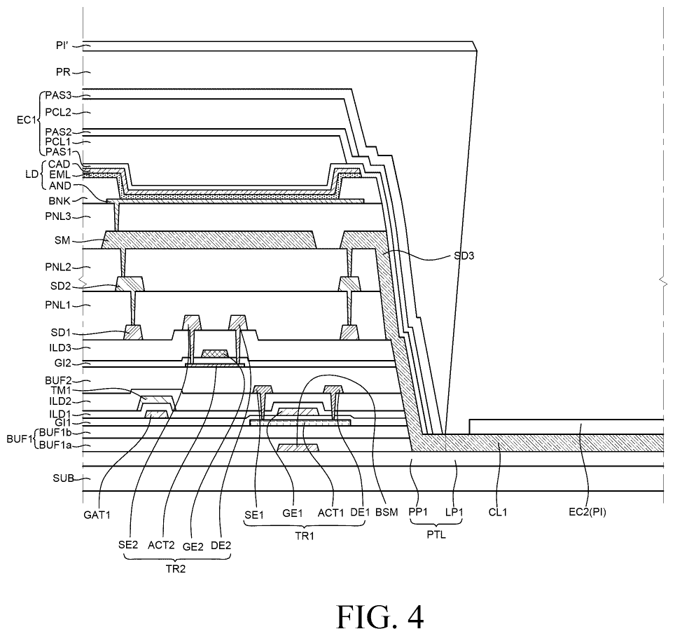

FIG. 1 is a top plan view of a display device according to an example embodiment of the present disclosure. FIG. 2 is an enlarged top plan view of a display area of the display device according to the example embodiment of the present disclosure. FIG. 3 is a cross-sectional view taken along line III-III′ in FIG. 2. FIG. 4 is a cross-sectional view for explaining a process of manufacturing a second encapsulation layer of the display device according to the example embodiment of the present disclosure.

First, a display device 100 according to an example embodiment of the present disclosure is a display device 100 capable of displaying images even when being bent or stretched. The display device 100 may also be referred to as a stretchable display device, a flexible display device, and an extendable display device. The display device 100 may have not only high flexibility but also stretchability in comparison with a general display device in the related art. Therefore, a user may bend or stretch the display device 100, and a shape of the display device 100 may be freely changed in accordance with the user's manipulation. For example, in case that the user holds and pulls an end of the display device 100, the display device 100 may be stretched in a direction in which the user pulls the display device. Alternatively, in case that the user disposes the display device 100 on a non-flat outer surface, the display device 100 may be disposed to be curved along a shape of an outer surface. In addition, when the force applied by the user is eliminated, the display device 100 may be restored back to an original shape.

With reference to FIGS. 1 to 3 together, a lower substrate SUB is a lower substrate SUB configured to support and protect several constituent elements of the display device 100. The lower substrate SUB may support a pattern layer PTL on which a pixel PX, a gate driver GD, and a power supply PS are formed. The lower substrate SUB may be a flexible substrate. In this case, the flexibility may be interpreted in the same way as bendable, unbreakable, rollable, and foldable properties and the like.

The lower substrate SUB may be made of an insulating material that is bendable or stretchable. For example, the lower substrate SUB may be made of silicone rubber such as polydimethylsiloxane (PDMS) or elastomer such as polyurethane (PU) and polytetrafluoroethylene (PTFE) and thus have flexibility. However, the material of the lower substrate SUB is proposed for illustrative purposes only. The material of the lower substrate SUB is not limited thereto.

The lower substrate SUB may be reversibly expanded and contracted. Therefore, the lower substrate SUB may also be referred to as a lower stretchable lower substrate SUB, an extendable lower substrate SUB, an expandable lower substrate SUB, a ductile lower substrate SUB, a flexible lower substrate SUB, a stretchable lower substrate SUB, or the like.

The lower substrate SUB includes a display area AA, and a non-display area NA configured to surround the display area AA. However, the display area AA and the non-display area NA may be referred to for explaining the entire display device 100 without being referred to for explaining only the lower substrate SUB.

The display area AA is an area of the display device 100 in which images are displayed. A plurality of pixels PX is disposed in the display area AA. Further, the pixels PX may each include display elements, and various driving elements for operating the display elements. Various driving elements may include at least one thin-film transistor (TFT) and at least one capacitor. However, the present disclosure is not limited thereto. The plurality of pixels PX may each be connected to various lines and operated. For example, the plurality of pixels PX may each be connected to various lines such as gate lines, data lines, high-potential voltage lines, low-potential voltage lines, reference voltage lines, and initialization voltage lines.

The non-display area NA is an area in which no image is displayed. The non-display area NA may be an area adjacent to the display area AA. Further, the non-display area NA may be an area disposed adjacent to the display area AA and configured to surround the display area AA. However, the present disclosure is not limited thereto. The non-display area NA may be an area of the lower substrate SUB that excludes the display area AA. The non-display area NA may be modified and divided into various shapes. The components, e.g., the gate driver GD and the power supply PS for operating the plurality of pixels PX disposed in the display area AA may be disposed in the non-display area NA. Further, a plurality of pads connected to a data driver DD and a printed circuit board PCB may be disposed in the non-display area NA. The pads may be respectively connected to the plurality of pixels PX in the display area AA.

The pattern layer PTL is disposed on the lower substrate SUB. The pattern layer PTL includes a plurality of first plate patterns PP1 and a plurality of first line patterns LP1 disposed in the display area AA, and a plurality of second plate patterns PP2 and a plurality of second line patterns LP2 disposed in the non-display area NA.

A plurality of plate patterns PP is disposed in the display area AA and the non-display area NA. The plurality of plate patterns PP includes the plurality of first plate patterns PP1 and the plurality of second plate patterns PP2. The plurality of first plate patterns PP1 is disposed in the display area AA of the lower substrate SUB, and the plurality of second plate patterns PP2 is disposed in the non-display area NA of the lower substrate SUB. The plurality of pixels PX may be formed on the plurality of first plate patterns PP1, and the gate drivers GD and the power supplies PS may be formed on the plurality of second plate patterns PP2.

The plurality of first plate patterns PP1 and the plurality of second plate patterns PP2 may be disposed in island shapes spaced apart from one another. The plurality of first plate patterns PP1 and the plurality of second plate patterns PP2 may be individually separated. Therefore, the plurality of first plate patterns PP1 and the plurality of second plate patterns PP2 may be referred to as first island patterns and second island patterns or first individual patterns and second individual patterns.

With reference to FIG. 1, a size of each of the plurality of second plate patterns PP2 may be larger than a size of each of the plurality of first plate patterns PP1. One stage of the gate driver GD may be disposed on each of the plurality of second plate patterns PP2. Therefore, an area occupied by various circuit components, which constitute one stage of the gate driver GD, is relatively larger than an area occupied by one pixel PX, such that a size of each of the plurality of second plate patterns PP2 may be larger than a size of each of the plurality of first plate patterns PP1.

Meanwhile, FIG. 1 illustrates that the plurality of second plate patterns PP2 is disposed in the non-display areas NA disposed at two opposite sides of the display area AA based on a first direction X. However, this is provided for illustrative purposes only. The plurality of second plate patterns PP2 may be disposed in any area of the non-display area NA. In addition, the plurality of first plate patterns PP1 and the plurality of second plate patterns PP2 are illustrated as each having a quadrangular shape. However, the present disclosure is not limited thereto. The plurality of first plate patterns PP1 and the plurality of second plate patterns PP2 may be modified in various shapes.

With reference to FIGS. 1 and 2, a plurality of line patterns LP is disposed in the display area AA and the non-display area NA. The plurality of line patterns LP includes the plurality of first line patterns LP1 and the plurality of second line patterns LP2. The plurality of first line patterns LP1 is disposed in the display area AA. The plurality of first line patterns LP1 may be patterns configured to connect the adjacent first plate patterns PP1 and also be referred to as inner connection patterns. That is, the plurality of first line patterns LP1 may be disposed between the plurality of first plate patterns PP1.

The plurality of second line patterns LP2 of the pattern layer PTL is disposed in the non-display area NA. The plurality of second line patterns LP2 may be patterns configured to connect the first plate patterns PP1 and the second plate patterns PP2, which are adjacent to one another, or connect the plurality of second plate patterns PP2 adjacent to one another and also be referred to as outer connection patterns. The plurality of second line patterns LP2 may be disposed between the first plate patterns PP1 and the second plate patterns PP2, which are adjacent to one another, and between the plurality of second plate patterns PP2 adjacent to one another.

The plurality of first line patterns LP1 and the plurality of second line patterns LP2 each have a curved shape. For example, the plurality of first line patterns LP1 and the plurality of second line patterns LP2 may each have a sinusoidal shape. However, the shapes of the plurality of first line patterns LP1 and the shapes of the plurality of second line patterns LP2 are not limited thereto. For example, the plurality of first line patterns LP1 and the plurality of second line patterns LP2 may each extend in a zigzag shape. Alternatively, the plurality of first line patterns LP1 and the plurality of second line patterns LP2 may have various shapes such as a shape in which a plurality of rhombic substrates is connected at vertices or a shape in which semicircular and quadrant substrates are connected to one another. In addition, the numbers and shapes of the plurality of first line patterns LP1 and the plurality of second line patterns LP2 illustrated in FIG. 1 are examples. The plurality of first line patterns LP1 and the plurality of second line patterns LP2 may be variously changed in numbers and shapes in accordance with design.

Meanwhile, the plurality of first plate patterns PP1, the plurality of first line patterns LP1, the plurality of second plate patterns PP2, and the plurality of second line patterns LP2 are each a rigid pattern. That is, the plurality of first plate patterns PP1, the plurality of first line patterns LP1, the plurality of second plate patterns PP2, and the plurality of second line patterns LP2 may be more rigid than the lower substrate SUB.

The plurality of first plate patterns PP1, the plurality of first line patterns LP1, the plurality of second plate patterns PP2, and the plurality of second line patterns LP2, which are rigid substrates, may each be made of a plastic material having lower flexibility than that of the lower substrate SUB. For example, the plurality of first plate patterns PP1, the plurality of first line patterns LP1, the plurality of second plate patterns PP2, and the plurality of second line patterns LP2 may each be made of at least one of polyimide (PI), polyacrylate, and polyacetate. In this case, in case that the plurality of first plate patterns PP1, the plurality of first line patterns LP1, the plurality of second plate patterns PP2, and the plurality of second line patterns LP2 are made of the same material, the plurality of first plate patterns PP1, the plurality of first line patterns LP1, the plurality of second plate patterns PP2, and the plurality of second line patterns LP2 may be integrated. However, the plurality of first plate patterns PP1, the plurality of first line patterns LP1, the plurality of second plate patterns PP2, and the plurality of second line patterns LP2 may be made of different materials. However, the present disclosure is not limited thereto.

The plurality of first plate patterns PP1, the plurality of first line patterns LP1, the plurality of second plate patterns PP2, and the plurality of second line patterns LP2 may each have an elastic modulus higher than an elastic modulus of the lower substrate SUB. The elastic modulus (modulus of elasticity) refers to a parameter that indicates a ratio of the lower substrate SUB deformed by stress applied to the lower substrate SUB. Hardness may increase relatively as the elastic modulus increases relatively. Therefore, the plurality of first plate patterns PP1, the plurality of first line patterns LP1, the plurality of second plate patterns PP2, and the plurality of second line patterns LP2 may be respectively referred to as a plurality of first rigid patterns, a plurality of second rigid patterns, a plurality of third rigid patterns, and a plurality of fourth rigid patterns. The plurality of first plate patterns PP1, the plurality of first line patterns LP1, the plurality of second plate patterns PP2, and the plurality of second line patterns LP2 may each have an elastic modulus that may be 1000 or more times higher than the elastic modulus of the lower substrate SUB. However, the present disclosure is not limited thereto.

Meanwhile, in several example embodiments, the lower substrate SUB may be defined to include a plurality of rigid areas RA and a plurality of soft areas SA. The plurality of rigid areas RA may be areas of the lower substrate SUB that overlap the pattern layer PTL. The soft area SA may be an area that does not overlap the pattern layer PTL. The pattern layer PTL is disposed in the plurality of rigid areas RA, and the pattern layer PTL is not disposed in the soft area SA, such that the plurality of rigid areas RA may be more rigid than the soft area SA. In this case, the soft area SA and the plurality of rigid areas RA may be referred to for explaining the entire display device 100 without being referred to for explaining only the lower substrate SUB.

The gate drivers GD may be mounted on the plurality of second plate patterns PP2.

The gate drivers GD may be formed on the plurality of second plate patterns PP2 in a gate-in-panel (GIP) manner when various constituent elements on the plurality of first plate patterns PP1 are manufactured. Therefore, various circuit components, e.g., transistors, capacitors, lines, and the like, which constitute the gate drivers GD, may be disposed on the plurality of second plate patterns PP2. One stage, which is a circuit that constitutes the gate driver GD and includes the transistor, the capacitor, and the like, may be disposed on an upper portion of each of the plurality of second plate patterns PP2. However, the gate driver GD may be mounted in a chip-on-film (COF) manner. However, the present disclosure is not limited thereto.

The power supplies PS are disposed on the plurality of second plate patterns PP2. The power supply PS may be formed on the second plate pattern PP2 adjacent to the gate driver GD. The power supply PS may be formed on the second plate pattern PP2 may be provided as a plurality of power blocks patterned when various constituent elements on the first plate pattern PP1 are manufactured. The power supply PS may be electrically connected to the gate driver GD in the non-display area NA and the plurality of pixels PX in the display area AA and supply a drive voltage. Specifically, the power supply PS may be electrically connected to the gate driver GD, which is formed on the second plate pattern PP2, and the plurality of pixels PX, which is formed on the first plate pattern PP1, through a second line pattern LP2 and a first line pattern LP1. For example, the power supply PS may supply a gate drive voltage and a clock signal to the gate driver GD. Further, the power supply PS may supply a power voltage to each of the plurality of pixels PX.

The printed circuit board PCB is connected to an edge of the lower substrate SUB. The printed circuit board PCB refers to a component that transmits signals and voltages for operating the display elements to the display elements from a controller. Therefore, the printed circuit board PCB may be referred to as a drive substrate. The controller such as IC chips and circuit parts may be mounted on the printed circuit board PCB. In addition, memories, processors, and the like may be mounted on the printed circuit board PCB. Further, the printed circuit board PCB provided in the display device 100 may include a stretchable area and a non-stretchable area to ensure stretchability. Further, IC chips, circuit parts, memories, processors, and the like may be mounted in the non-stretchable area. Lines electrically connected to the IC chips, the circuit parts, the memories, and the processors may be disposed in the stretchable area.

The data driver DD is a constituent element configured to supply data voltages to the plurality of pixels PX disposed in the display area AA. The data driver DD may be configured in the form of an IC chip, and thus referred to as a data integrated circuit (D-IC). Further, the data driver DD may be mounted in the non-stretchable area of the printed circuit board PCB. That is, the data driver DD may be mounted on the printed circuit board PCB in a chip-on-board (COB) manner. However, FIG. 1 illustrates that the data driver DD is mounted in a chip-on-board (COB) manner. However, the present disclosure is not limited thereto. The data driver DD may be mounted in a chip-on-film (COF) manner, a chip-on-glass (COG) manner, a tape carrier package (TCP) manner, and the like.

In addition, FIG. 1 illustrates that a single data driver DD is disposed to correspond to each of the plurality of columns in which the plurality of first plate patterns PP1 is disposed in the display area AA. However, the present disclosure is not limited thereto. That is, a single data driver DD may be disposed to correspond to a plurality of columns in which the plurality of first plate patterns PP1 is disposed.

With reference to FIGS. 1 and 2, the plurality of first plate patterns PP1 is spaced apart from one another and disposed in the display area AA of the lower substrate SUB. For example, as illustrated in FIG. 1, the plurality of first plate patterns PP1 may be disposed in matrix shape on the lower substrate SUB. However, the present disclosure is not limited thereto. Further, the plurality of first line patterns LP1 may connect the plurality of first plate patterns PP1. Some of the plurality of first line patterns LP1 may connect the plurality of first plate patterns PP1 adjacent to one another in the first direction X, and some of the remaining first line patterns LP1 may connect the plurality of first plate patterns PP1 adjacent to one another in a second direction Y.

With reference to FIGS. 2 and 3, the pixel PX including a plurality of subpixels SPX, which are individual units configured to emit light, is disposed on each of the plurality of first plate patterns PP1. The plurality of subpixels SPX may each include a light-emitting element LD, which is a display element, and a pixel circuit configured to operate the light-emitting element LD. The light-emitting element LD may be configured as an organic light-emitting diode or an inorganic light-emitting diode such as a micro LED (light emitting diode) or a quantum dot light-emitting diode. In addition, the light-emitting element LD may be a light-emitting element LD in which an organic material and an inorganic material are complexly configured. Further, the plurality of pixels PX may each include a single light-emitting element LD. In another example embodiment, the plurality of pixels PX may each include the plurality of light-emitting elements LD, and the plurality of light-emitting elements LD may be connected to one another in series, parallel, or both series and parallel. The display device 100 may display images by operating the plurality of pixels PX in response to inputted image data.

Meanwhile, the plurality of subpixels SPX may include red subpixels SPX, green subpixels SPX, and blue subpixels SPX. According to the example embodiment, at least some of the plurality of pixels PX may further include white subpixels SPX. The plurality of subpixels SPX may be variously modified in colors and configurations, as necessary. However, the present disclosure is not limited thereto.

A plurality of connection lines CL is disposed on the plurality of line patterns LP. The plurality of connection lines CL may be lines configured to electrically connect the pads of the plurality of first plate patterns PP1 and the pads of the plurality of second plate patterns PP2. The plurality of connection lines CL is disposed between the plurality of first plate patterns PP1, between the plurality of second plate patterns PP2, and between the plurality of first plate patterns PP1 and the plurality of second plate patterns PP2. The plurality of connection lines CL may electrically connect the pads on the plurality of first plate patterns PP1, electrically connect the pads on the plurality of second plate patterns PP2, and electrically connect the pads on the plurality of first plate patterns PP1 and the pads on the plurality of second plate patterns PP2.

The plurality of connection lines CL includes first connection lines CL1 and second connection lines CL2. The first connection lines CL1 are lines extending in the first direction X between the plurality of first plate patterns PP1, between the plurality of second plate patterns PP2, and between the plurality of first plate patterns PP1 and the plurality of second plate patterns PP2. The second connection lines CL2 are lines extending in the second direction Y between the plurality of first plate patterns PP1, between the plurality of second plate patterns PP2, and between the plurality of first plate patterns PP1 and the plurality of second plate patterns PP2. The plurality of connection lines CL may each have a shape corresponding to the line pattern LP. For example, the connection line CL may have a curved shape. The plurality of connection lines CL may each have a sinusoidal shape.

The plurality of connection lines CL may each be configured as a layered structure made of a metallic material such as copper (Cu), aluminum (Al), titanium (Ti), or molybdenum (Mo) or a metallic material such as copper/molybdenum-titanium (Cu/Mo—Ti) or titanium/aluminum/titanium (Ti/Al/Ti). However, the present disclosure is not limited thereto.

Meanwhile, in the case of a general display device, various lines such as a plurality of gate lines and a plurality of data lines are disposed between a plurality of subpixels and extend in straight shapes. The plurality of subpixels is connected to the single signal line. Therefore, in the case of the general display device, various lines such as the gate line, the data line, the high-potential voltage line, and the reference voltage line extend in a direction from one side to the other side without interruption on the substrate.

In contrast, in the case of the display device 100 according to the example embodiment of the present disclosure, various lines, such as gate lines, data lines, high-potential voltage lines, reference voltage lines, and initialization voltage lines, which are straight lines that may be considered as being used for the general display device, are disposed only on the plurality of first plate patterns PP1 and the plurality of second plate patterns PP2. That is, in the display device 100 according to the example embodiment of the present disclosure, the straight lines may be disposed only on the plurality of first plate patterns PP1 and the plurality of second plate patterns PP2.

In the display device 100 according to the example embodiment of the present disclosure, the pads on the two adjacent first plate patterns PP1 may be connected by the connection line CL. Therefore, the connection line CL electrically connects the pads on the two adjacent first plate patterns PP1. Therefore, the display device 100 according to the example embodiment of the present disclosure may include the plurality of connection lines CL to electrically connect various lines, such as the gate lines, data line, the high-potential voltage lines, and the reference voltage lines, between the plurality of first plate patterns PP1. For example, the gate line may be disposed on the plurality of first plate patterns PP1 disposed adjacent to one another in the first direction X, and the gate pads may be disposed at two opposite ends of the gate line. In this case, the plurality of gate pads on the plurality of first plate patterns PP1 disposed adjacent to one another in the first direction X may be connected to one another by the first connection line CL1 that serves as a gate line. Therefore, the gate line, which is disposed on the plurality of first plate patterns PP1, and the first connection line CL1, which is disposed on the first line pattern LP1, may serve as a single gate line. In addition, among all the various lines that may be included in the display device 100, the line extending in the first direction X, for example, the light-emitting signal line, the low-potential voltage line, and the high-potential voltage line may also be electrically connected by the first connection line CL1, as described above.

Among the plurality of second connection lines CL2, some of the second connection lines CL2 may connect the pads on the plurality of first plate patterns PP2 disposed adjacent to one another in the second direction Y. Internal lines on the plurality of first plate patterns PP1 disposed in the second direction Y may be connected by the plurality of second connection lines CL2 that serves as the data lines, such that the single data voltage may be transmitted. However, the plurality of second connection lines CL2 may serve as the data lines, the high-potential voltage lines, the low-potential voltage lines, or the reference lines. However, the present disclosure is not limited thereto.

Hereinafter, a cross-sectional structure of the display area AA will be specifically described with reference to FIG. 3.

With reference to FIG. 3, a first shield pattern BSM is disposed on the lower substrate SUB and the first plate pattern PP1. The first shield pattern BSM may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. According to the example embodiment, the first shield pattern BSM may be defined as a constituent element of a first transistor TR1. For example, the first shield pattern BSM may serve as a lower gate electrode of the first transistor TR1.

A first buffer layer BUF1 is disposed on the first shield pattern BSM and the first plate pattern PP1. The first buffer layer BUF1 may be formed on the plurality of first plate patterns PP1 in order to cover the first shield pattern BSM and protect various constituent elements of the display device 100 from the penetration of moisture and oxygen from the outside of the lower substrate SUB and the first plate pattern PP1. The first buffer layer BUF1 includes a multi-buffer layer BUF1a and an active buffer layer BUF1b. The first buffer layer BUF1 may be made of an insulating material. For example, the first buffer layer BUF1 may be configured as a single layer or multilayer made of at least one of silicon nitride (SiNx), silicon oxide (SiOx), and silicon oxynitride (SiON). However, the first buffer layer BUF1 may be excluded in accordance with the structure or properties of the display device 100.

The first transistor TR1 is disposed on the first buffer layer BUF1. The first transistor TR1 includes a first active layer ACT1, a first gate electrode GE1, a first source electrode SE1, and a first drain electrode DE1. According to the example embodiment, the first transistor TR1 may further include a shield metal pattern as a gate electrode.

The first active layer ACT1 is disposed on the first buffer layer BUF1. The first active layer ACT1 may include a source area connected to the first source electrode SE1, a drain area connected to the first drain electrode DE1, and a channel area between the source area and the drain area. The first active layer ACT1 may include a polysilicon semiconductor layer formed by a low-temperature polysilicon (LTPS) process.

A first gate insulation layer GI1 is disposed on the first active layer ACT1. The first gate insulation layer GI1 is an insulation layer for insulating the first active layer ACT1 and the first gate electrode GE1. The first gate insulation layer GI1 may be configured as a single layer or multilayer made of silicon nitride (SiNx) or silicon oxide (SiOx). However, the present disclosure is not limited thereto.

The first gate electrode GE1 is disposed on the first gate insulation layer GI1. The first gate electrode GE1 is disposed to overlap the first active layer ACT1 with the first gate insulation layer GI1 interposed therebetween. The first gate electrode GE1 may be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the first gate electrode GE1 may be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

A first interlayer insulation layer ILD1 is disposed on the first gate electrode GE1, and a second interlayer insulation layer ILD2 is disposed on the first interlayer insulation layer ILD1. The first interlayer insulation layer ILD1 and the second interlayer insulation layer ILD2 are disposed to cover the first gate electrode GE1, a first conductive layer GAT1, and a second conductive layer TM1. The first interlayer insulation layer ILD1 and the second interlayer insulation layer ILD2 may each be configured as a single layer or multilayer made of silicon nitride (SiNx) or silicon oxide (SiOx). However, the present disclosure is not limited thereto.

The first source electrode SE1 and the first drain electrode DE1 are disposed on the second interlayer insulation layer ILD2. The first source electrode SE1 and the first drain electrode DE1 may be electrically connected to the first active layer ACT1 through contact holes formed in the second interlayer insulation layer ILD2, the first interlayer insulation layer ILD1, and the first gate insulation layer GI1. The first source electrode SE1 and the first drain electrode DE1 may each be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the first source electrode SE1 and the first drain electrode DE1 may each be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

The first conductive layer GAT1 is disposed between the first gate insulation layer GI1 and the first interlayer insulation layer ILD1. The first conductive layer GAT1 may constitute at least a part of a light emission control line configured to provide a light-emitting control signal to the pixel PX, at least a part of a scan line configured to provide a scan signal, and at least a part of a power line configured to provide various types of power voltages. In this case, in case that the first conductive layer GAT1 constitutes at least a part of the power line configured to provide a power voltage, the first conductive layer GAT1 may be made of a material, such as metal or conductive oxide, with high conductivity. For example, the first conductive layer GAT1 may be configured as a single layer or multilayer including aluminum (Al), copper (Cu), titanium (Ti), and the like. In some example embodiments, the first conductive layer GAT1 may be provided as a triple layer in which titanium, aluminum, and titanium (Ti/Al/Ti) are sequentially disposed. However, the configuration of the first conductive layer GAT1 is not limited thereto. The first conductive layer GAT1 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. In addition, the first gate electrode GE1, which is disposed on the same layer as the first conductive layer GAT1, may be configured as the first conductive layer GAT1 that constitutes at least a part of the light emission control line or the scan line of the first conductive layer GAT1.

The second conductive layer TM1 is disposed between the first interlayer insulation layer ILD1 and the second interlayer insulation layer ILD2. The second conductive layer TM1 may be configured as a single layer or multilayer including molybdenum (Mo), copper (Cu), titanium (Ti), and the like. The second conductive layer TM1 may be disposed to overlap the first conductive layer GAT1 and serve as a kind of capacitor electrode.

A second buffer layer BUF2 is disposed on the second interlayer insulation layer ILD2. The second buffer layer BUF2 is disposed to cover the first source electrode SE1 and the first drain electrode DE1 of the first transistor TR1. The second buffer layer BUF2 may be configured as a single layer or multilayer made of silicon nitride (SiNx) or silicon oxide (SiOx). However, the present disclosure is not limited thereto.

A second transistor TR2 is disposed on the second buffer layer BUF2. The second transistor TR2 includes a second active layer ACT2, the second gate electrode GE2, a second source electrode SE2, and a second drain electrode DE2.

First, the second active layer ACT2 is disposed on the second buffer layer BUF2. The second active layer ACT2 may include a source area connected to the second source electrode SE2, a drain area connected to the second drain electrode DE2, and a channel area between the source area and the drain area. The second active layer ACT2 may include an oxide semiconductor layer.

A second gate insulation layer GI2 is disposed on the second active layer ACT2. The second gate insulation layer GI2 is an insulation layer for insulating the second active layer ACT2 and the second gate electrode GE2. The second gate insulation layer GI2 may be configured as a single layer or multilayer made of silicon nitride (SiNx) or silicon oxide (SiOx). However, the present disclosure is not limited thereto.

The second gate electrode GE2 is disposed on the second gate insulation layer GI2.

The second gate electrode GE2 is disposed to overlap the second active layer ACT2 with the second gate insulation layer GI2 interposed therebetween. The second gate electrode GE2 may constitute at least a part of the scan line. The second gate electrode GE2 may be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the second gate electrode GE2 may be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

A third interlayer insulation layer ILD3 is disposed on the second gate electrode GE2. The third interlayer insulation layer ILD3 is disposed to cover the second gate electrode GE2. The third interlayer insulation layer ILD3 may be configured as a single layer or multilayer made of silicon nitride (SiNx) or silicon oxide (SiOx). However, the present disclosure is not limited thereto.

The second source electrode SE2 and the second drain electrode DE2 are disposed on the third interlayer insulation layer ILD3. The second source electrode SE2 and the second drain electrode DE2 may be electrically connected to the second active layer ACT2 through contact holes formed in the third interlayer insulation layer ILD3 and the second gate insulation layer GI2. The second source electrode SE2 and the second drain electrode DE2 may each be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the second source electrode SE2 and the second drain electrode DE2 may each be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

A third conductive layer SD1 is disposed on the third interlayer insulation layer ILD3. The third conductive layer SD1 may constitute at least a part of the power line configured to provide a power voltage. In this case, because the third conductive layer SD1 constitutes at least a part of the power line configured to provide a power voltage, the third conductive layer SD1 may be made of a material, such as metal or conductive oxide, with high conductivity. For example, the third conductive layer SD1 may be configured as a single layer or multilayer including aluminum (Al), copper (Cu), titanium (Ti), and the like. In some example embodiments, the third conductive layer SD1 may be provided as a triple layer in which titanium, aluminum, and titanium (Ti/Al/Ti) are sequentially disposed. However, the configuration of the third conductive layer SD1 is not limited thereto. The third conductive layer SD1 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

In addition, at least a part of the third conductive layer SD1 may serve as a connection electrode. For example, at least a part of the third conductive layer SD1 may be connected to a conductive layer, which is formed between the second buffer layer BUF2 and the second interlayer insulation layer ILD2, through contact holes formed through the third interlayer insulation layer ILD3, the second gate insulation layer GI2, and the second buffer layer BUF2. Alternatively, at least a part of the third conductive layer SD1 may be connected to a conductive layer, which is formed between the third interlayer insulation layer ILD3 and the second gate insulation layer GI2, through a contact hole formed through the third interlayer insulation layer ILD3. Further, at least a part of the third conductive layer SD1 may be connected to another conductive layer disposed on the third conductive layer SD1. Further, at least a part of the third conductive layer SD1 may constitute the second source electrode SE2 and the second drain electrode DE2 of the second transistor TR2.

A first planarization layer PNL1 is disposed on the third conductive layer SD1 and the second transistor TR2. The first planarization layer PNL1 is an insulation layer configured to planarize an upper portion of the first planarization layer PNL1 and protect other constituent elements disposed below the first planarization layer PNL1. For example, the first planarization layer PNL1 may be made of an organic material such as acrylic resin, epoxy resin, phenolic resin, polyamide resin, and polyimide resin. However, the present disclosure is not limited thereto.

A fourth conductive layer SD2 is disposed on the first planarization layer PNL1. The fourth conductive layer SD2 may constitute at least a part of the data line configured to provide a data signal to the pixel PX or at least a part of the power line configured to provide a high-potential power voltage. In this case, because the fourth conductive layer SD2 constitutes at least a part of the power line configured to provide a power voltage, the fourth conductive layer SD2 may be made of a material, such as metal or conductive oxide, with high conductivity. For example, the fourth conductive layer SD2 may be configured as a single layer or multilayer including aluminum (Al), copper (Cu), titanium (Ti), and the like. In some example embodiments, the fourth conductive layer SD2 may be provided as a triple layer in which titanium, aluminum, and titanium (Ti/Al/Ti) are sequentially disposed. However, the fourth conductive layer SD2 is not limited thereto. The fourth conductive layer SD2 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. In addition, at least a part of the fourth conductive layer SD2 may serve as a connection electrode. For example, at least a part of the fourth conductive layer SD2 may be connected to at least a part of the third conductive layer SD1 through a contact hole formed through the first planarization layer PNL1.

A second planarization layer PNL2 is disposed on the fourth conductive layer SD2.

The second planarization layer PNL2 is an insulation layer configured to planarize an upper portion of the second planarization layer PNL2 and protect other constituent elements disposed below the second planarization layer PNL2. For example, the second planarization layer PNL2 may be made of an organic material such as acrylic resin, epoxy resin, phenolic resin, polyamide resin, and polyimide resin. However, the present disclosure is not limited thereto.

A second shield pattern SM is disposed on the second planarization layer PNL2. A signal interference may occur between conductive layers below the second shield pattern SM and an anode electrode AND of the light-emitting element LD disposed on the second shield pattern SM. In this case, a voltage of the anode electrode AND may fluctuate, and the display quality may deteriorate. Therefore, the second shield pattern SM may be disposed on the second planarization layer PNL2, overlap the anode electrode AND, and block signals between the conductive layers below the second shield pattern SM and the anode electrode AND on the second shield pattern SM, which may stably maintain a voltage of the anode electrode AND and improve the display quality. The second shield pattern SM may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

A fifth conductive layer SD3 is disposed on the second planarization layer PNL2. The fifth conductive layer SD3 may be connected to at least a part of the fourth conductive layer SD2 through a contact hole formed through the second planarization layer PNL2. The fifth conductive layer SD3 may extend to side surfaces of a plurality of insulation layers disposed below the fifth conductive layer SD3 and be connected to the connection line CL disposed in the soft area SA. For example, the fifth conductive layer SD3 may extend from a top surface of the second planarization layer PNL2 to a side surface of the second planarization layer PNL2, a side surface of the first planarization layer PNL1, a side surface of the third interlayer insulation layer ILD3, a side surface of the second gate insulation layer GI2, a side surface of the second buffer layer BUF2, a side surface of the second interlayer insulation layer ILD2, a side surface of the first interlayer insulation layer ILD1, a side surface of the first gate insulation layer GI1, and a side surface of the first buffer layer BUF1 and be connected to the connection line CL disposed on the first line pattern LP1. Therefore, the fifth conductive layer SD3 may be a conductive layer configured to electrically connect the plurality of connection lines CL and various types of lines disposed on the first plate pattern PP1. In addition, at least a part of the fifth conductive layer SD3 may serve as the second shield pattern SM. The fifth conductive layer SD3 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

A third planarization layer PNL3 is disposed on the fifth conductive layer SD3 and the second shield pattern SM. The third planarization layer is an insulation layer configured to planarize an upper portion of the second planarization layer PNL2 and protect other constituent elements disposed below the second planarization layer PNL2. For example, the third planarization layer PNL3 may be made of an organic material such as acrylic resin, epoxy resin, phenolic resin, polyamide resin, and polyimide resin. However, the present disclosure is not limited thereto.

The light-emitting element LD is disposed on the third planarization layer PNL3. The light-emitting element LD includes the anode electrode AND, a light-emitting layer EML, and a cathode electrode CAD.

The anode electrode AND is disposed on the third planarization layer PNL3. For example, the anode electrode AND may be made of a transparent electrically conductive material such as indium tin oxide (ITO) or indium zinc oxide (IZO). However, the present disclosure is not limited thereto.

Meanwhile, in case that the display device 100 according to the example embodiment of the present disclosure is a top emission type display device, the anode electrode AND may further include a reflective layer made of a metallic material, for example, a material such as aluminum (Al) or silver (Ag) excellent in reflection efficiency so that light emitted from the light-emitting layer EML is reflected by the anode electrode AND and propagates upward direction, i.e., toward the cathode electrode CAD. On the contrary, in case that the display device 100 is a bottom emission type display device, the anode electrode AND may be made of only a transparent electrically conductive material.

A bank BNK is disposed on the third planarization layer PNL3 and covers a part of the anode electrode AND. The bank BNK may be disposed to cover a part of an edge of the anode electrode AND, and a part of the anode electrode AND, which is exposed from the bank BNK, may correspond to a light-emitting area. The bank BNK may be disposed at a boundary between the plurality of subpixels SPX and suppress a color mixture of light beams from the plurality of subpixels SPX. The bank BNK may include an inorganic insulating material, such as silicon nitride (SiNx) or silicon oxide (SiOx), or an organic insulating material such as benzocyclobutene (BCB)-based resin, acrylic resin, or polyimide. However, the present disclosure is not limited thereto.

The light-emitting layer EML is disposed on the bank BNK and the anode electrode AND. The light-emitting layer EML may adjoin a part of the anode electrode AND exposed from the bank BNK. The light-emitting layer EML may be disposed on a front surface of the rigid area RA in which the first plate pattern PP1 is disposed. The light-emitting layer EML may further include organic material layers such as a hole injection layer, a hole transport layer, an electron transport layer, and an electron injection layer.

The cathode electrode CAD is disposed on the light-emitting layer EML. Like the light-emitting layer EML, the cathode electrode CAD may also be disposed on the front surface of the rigid area RA in which the first plate pattern PP1 is disposed. Because the cathode electrode CAD supplies electrons to the light-emitting layer EML, the cathode electrode CAD may be made of an electrically conductive material with a low work function. For example, the cathode electrode CAD may be made of a transparent electrically conductive material such as indium tin oxide (ITO) or indium zinc oxide (IZO) or made of an alloy of ytterbium (Yb). The cathode electrode CAD may further include a metal doping layer. However, the present disclosure is not limited thereto.

A first encapsulation layer EC1 is disposed on the light-emitting element LD. The first encapsulation layer EC1 has a structure in which inorganic encapsulation layers and organic encapsulation layers are alternately stacked, such that the first encapsulation layer EC1 may protect the light-emitting element LD while inhibiting moisture or oxygen from penetrating into the light-emitting element LD. For example, the first encapsulation layer EC1 includes a first inorganic encapsulation layer PAS1, a first organic encapsulation layer PCL1, a second inorganic encapsulation layer PAS2, a second organic encapsulation layer PCL2, and a third inorganic encapsulation layer PAS3 stacked sequentially.

The first inorganic encapsulation layer PAS1, the second inorganic encapsulation layer PAS2, and the third inorganic encapsulation layer PAS3 may serve to block the penetration of moisture or oxygen. The first inorganic encapsulation layer PAS1, the second inorganic encapsulation layer PAS2, and the third inorganic encapsulation layer PAS3 may be made of an inorganic material, for example, an inorganic material such as silicon nitride (SiNx), silicon oxide (SiOx), or aluminum oxide (AlOx). However, the present disclosure is not limited thereto.

The first inorganic encapsulation layer PAS1, the second inorganic encapsulation layer PAS2, and the third inorganic encapsulation layer PAS3 may each entirely cover upper portions and side surfaces of the components disposed in the rigid area RA. For example, the first inorganic encapsulation layer PAS1, the second inorganic encapsulation layer PAS2, and the third inorganic encapsulation layer PAS3 may cover the upper portion of the light-emitting element LD disposed above the first plate pattern PP1. The first inorganic encapsulation layer PAS1, the second inorganic encapsulation layer PAS2, and the third inorganic encapsulation layer PAS3 may be disposed between the light-emitting element LD and the first plate pattern PP1 and cover the side surfaces of the plurality of insulation layers, which are exposed to the outside, and the fifth conductive layer SD3 disposed on the side surfaces of the plurality of insulation layers. The first inorganic encapsulation layer PAS1, the second inorganic encapsulation layer PAS2, and the third inorganic encapsulation layer PAS3 may extend to a boundary between the rigid area RA and the soft area SA.

Further, the first inorganic encapsulation layer PAS1, the second inorganic encapsulation layer PAS2, and the third inorganic encapsulation layer PAS3 may adjoin one another at the boundary between the rigid area RA and the soft area SA and seal the first organic encapsulation layer PCL1 and the second organic encapsulation layer PCL2. For example, the first inorganic encapsulation layer PAS1 and the second inorganic encapsulation layer PAS2 may seal the first organic encapsulation layer PCL1 while adjoining one another on an outer peripheral portion of the rigid area RA, and the second inorganic encapsulation layer PAS2 and the third inorganic encapsulation layer PAS3 may seal the second organic encapsulation layer PCL2 while adjoining one another on the outer peripheral portion of the rigid area RA.

The first organic encapsulation layer PCL1 is disposed between the first inorganic encapsulation layer PAS1 and the second inorganic encapsulation layer PAS2, and the second organic encapsulation layer PCL2 is disposed between the second inorganic encapsulation layer PAS2 and the third inorganic encapsulation layer PAS3. The first organic encapsulation layer PCL1 and the second organic encapsulation layer PCL2 may each have a larger thickness than the first inorganic encapsulation layer PAS1, the second inorganic encapsulation layer PAS2, and the third inorganic encapsulation layer PAS3 in order to adsorb or block particles that may be produced during a process of manufacturing the display device 100. The first organic encapsulation layer PCL1 and the second organic encapsulation layer PCL2 may fill cracks that may be formed in the first inorganic encapsulation layer PAS1 and the second inorganic encapsulation layer PAS2. The first organic encapsulation layer PCL1 and the second organic encapsulation layer PCL2 may planarize an upper portion of the first inorganic encapsulation layer PAS1 and an upper portion of the second inorganic encapsulation layer PAS2 by covering particles on the first inorganic encapsulation layer PAS1 and the second inorganic encapsulation layer PAS2. The first organic encapsulation layer PCL1 and the second organic encapsulation layer PCL2 may be made of an organic material, and for example, epoxy polymer, acrylic polymer, or the like may be used. However, the present disclosure is not limited thereto.

Next, a second encapsulation layer EC2 is disposed on the connection line CL in the soft area SA. The second encapsulation layer EC2 may be disposed to cover the connection line CL and protect the connection line CL so that the connection line CL is not oxidized and damaged by moisture, oxygen, or the like. The second encapsulation layer EC2 may be made of a material different from materials of the first encapsulation layer EC1. For example, the second encapsulation layer EC2 may be made of a material, such as polyimide, having insulation and flexibility. The second encapsulation layer EC2 may include polyimide layer (PI). Therefore, the second encapsulation layer EC2 may be made of a material with flexibility and ensure stretchability and reliability of a stretchable line.

Meanwhile, with reference to FIGS. 3 and 4 together, a fluorine-based residual film FL may be formed on the front surface of the lower substrate SUB having the first encapsulation layer EC1 and the second encapsulation layer EC2 during a process of forming the second encapsulation layer EC2. For example, a photoresist pattern PR is formed to cover the rigid area RA, i.e., the remaining area excluding the soft area SA in which the second encapsulation layer EC2 is to be formed. The photoresist pattern PR may have an inversely tapered shape to disconnect a polyimide layer PI′ on the photoresist pattern PR and a polyimide layer PI formed in an area in which the photoresist pattern PR is not present. The photoresist pattern PR may be made of a fluorine-based material. The photoresist pattern PR may be disposed to cover the entire rigid area RA formed to the first encapsulation layer EC1.

Further, a material, which constitutes the second encapsulation layer EC2, may be formed on the front surface of the lower substrate SUB on which the photoresist pattern PR is formed. For example, the polyimide layers PI and PI′, which are materials constituting the second encapsulation layer EC2, may be formed on the front surface of the lower substrate SUB. The polyimide layers PI and PI′ may be disposed to cover the photoresist pattern PR in the rigid area RA, e.g., the area in which the photoresist pattern PR is formed. The polyimide layers PI and PI′ may be disposed to cover the connection line CL and the like in the soft area SA, e.g., the area in which the photoresist pattern PR is not formed. In this case, as described above, the photoresist pattern PR may have an inversely tapered shape, such that the polyimide layers PI and PI′ may be disconnected at the edge of the photoresist pattern PR. For example, the polyimide layers PI and PI′, which are formed on the front surface of the lower substrate SUB, are disconnected at the edge of the photoresist pattern PR having an inversely tapered shape, such that the polyimide layers PI and PI′ may be divided into the polyimide layer PI′, which is disposed on the photoresist pattern PR, and the polyimide layer PI disposed in the area in which the photoresist pattern PR is not present.

Further, the photoresist pattern PR may be removed by using a fluorine-based solution. In this process, the polyimide layer PI′ formed on the photoresist pattern PR may be removed together with the photoresist pattern PR, and the polyimide layer PI, which is disposed in the soft area SA without being formed on the photoresist pattern PR, may remain in an intact manner and become the second encapsulation layer EC2.

Specifically, the fluorine-based solution may be applied onto the front surface of the lower substrate SUB at the time of removing the photoresist pattern PR. Therefore, the fluorine-based residual film FL may be formed from the fluorine-based solution and cover the front surface of the lower substrate SUB having the first encapsulation layer EC1 and the second encapsulation layer EC2. The fluorine-based residual film FL may be a monomolecular or composite polymer having plurality of fluorine-based materials included in a carbon-carbon backbone. The fluorine-based material may have solvent orthogonality and allow an organic material and a moisture layer to be separated and excluded from each other, which may inhibit the organic material and the moisture layer from moving to different layers. Therefore, the fluorine-based residual film FL is formed on the front surface of the lower substrate SUB having the first encapsulation layer EC1 and the second encapsulation layer EC2, which may delay the penetration of moisture or the like into other components below the first encapsulation layer EC1 and the second encapsulation layer EC2.

Meanwhile, a part of the connection line CL may be sometimes exposed from the second encapsulation layer EC2 in the vicinity of the boundary between the rigid area RA and the soft area SA. The first encapsulation layer EC1 and the second encapsulation layer EC2 are formed by different processes and made of different materials, such that the first encapsulation layer EC1 and the second encapsulation layer EC2 may not be connected to each other. In this case, a part of the connection line CL may be exposed in a space between the first encapsulation layer EC1 and the second encapsulation layer EC2. In this case, the fluorine-based residual film FL may also cover a part of the connection line CL while being formed to cover the front surface of the lower substrate SUB having the first encapsulation layer EC1 and the second encapsulation layer EC2. That is, even though a part of the connection line CL is exposed from the second encapsulation layer EC2, the fluorine-based residual film FL may cover the remaining exposed portion of the connection line CL and protect the connection line CL from outside moisture or the like. Therefore, the fluorine-based residual film FL, together with the second encapsulation layer EC2, may protect the connection line CL.

Therefore, in the display device 100 according to the example embodiment of the present disclosure, the first encapsulation layer EC1 is disposed in the rigid area RA to protect the light-emitting element LD, and the second encapsulation layer EC2 is disposed in the soft area SA to protect the connection line CL, which may protect the display device 100 from moisture and oxygen. The first encapsulation layer EC1 may be disposed to seal the light-emitting element LD disposed in the rigid area RA and protect the light-emitting element LD so that the light-emitting element LD is not degraded by moisture, oxygen, and the like. Further, the second encapsulation layer EC2 may be disposed to cover the connection line CL and protect the connection line CL to suppress damage to the connection line CL such as oxidation of the connection line CL. In this case, the second encapsulation layer EC2 may be configured as the polyimide layer PI having flexibility, such that the connection line CL may be easily stretched.

Further, in the display device 100 according to the example embodiment of the present disclosure, the fluorine-based residual film FL may be formed on the front surface of the display device 100 by using the fluorine-based solution as a solution for removing the photoresist pattern PR at the time of forming the second encapsulation layer EC2. The photoresist pattern PR may be removed by applying the fluorine-based solution onto the front surface of the lower substrate SUB on which the first encapsulation layer EC1 and the second encapsulation layer EC2 are formed. Further, the fluorine-based residual film FL, which is applied with a very small thickness on the front surface of the lower substrate SUB having the first encapsulation layer EC1 and the second encapsulation layer EC2, may be formed by the fluorine-based solution. The fluorine-based residual film FL may protect the constituent elements of the display device 100 by delaying the penetration of moisture into the first encapsulation layer EC1 and the second encapsulation layer EC2 below the fluorine-based residual film FL.

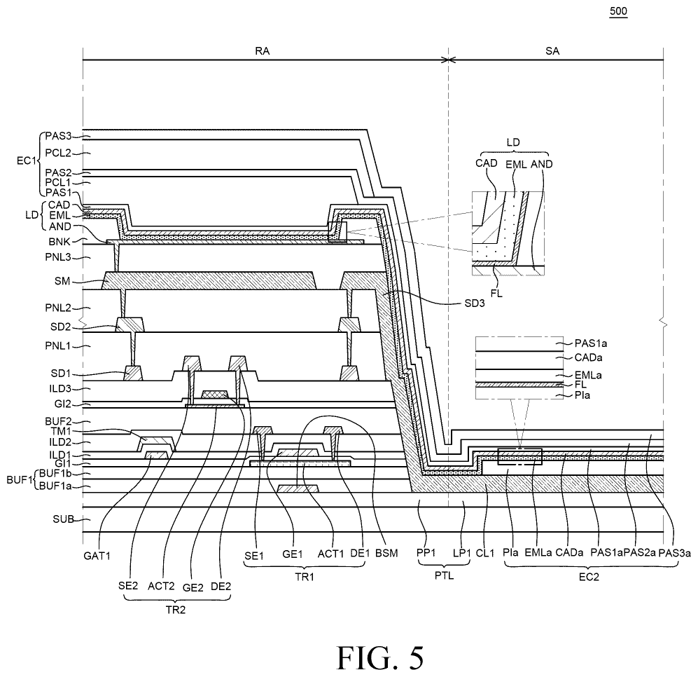

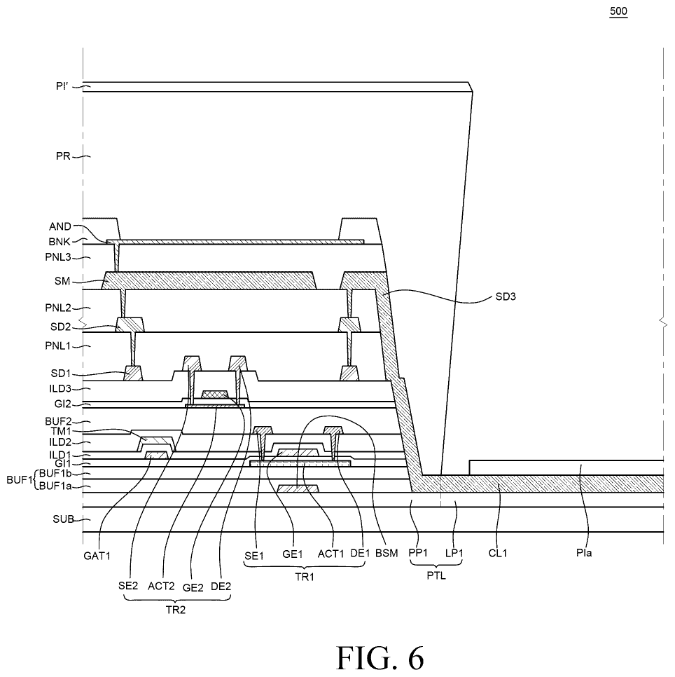

FIG. 5 is a cross-sectional view of a display device according to another example embodiment of the present disclosure. FIG. 6 is a cross-sectional view for explaining a process of manufacturing a second encapsulation layer of the display device according to another example embodiment of the present disclosure. A display device 500 illustrated in FIGS. 5 and 6 is substantially identical in configuration to the display device 100 illustrated in FIGS. 1 to 4, except for the second encapsulation layer EC2. Therefore, repeated descriptions of the identical components will be omitted.

With reference to FIG. 5, the second encapsulation layer EC2 may include a plurality of layers and, for example, include a first line encapsulation layer P1a, a second line encapsulation layer EMLa, a third line encapsulation layer CADa, a fourth line encapsulation layer PAS1a, a fifth line encapsulation layer PAS2a, and a sixth line encapsulation layer PAS3a.

The first line encapsulation layer P1a may be disposed to cover the soft area SA in which the connection line CL is disposed. The first line encapsulation layer P1a may be a polyimide layer and adjoin the connection line CL.

The second line encapsulation layer EMLa is disposed on the first line encapsulation layer P1a. The light-emitting layer EML of the light-emitting element LD disposed in the rigid area RA may extend to the soft area SA, thereby defining the second line encapsulation layer EMLa. The light-emitting layer EML may be formed on the front surface of the lower substrate SUB, and a part of the light-emitting layer EML disposed in the soft area SA may become the second line encapsulation layer EMLa.

The third line encapsulation layer CADa is disposed on the second line encapsulation layer EMLa. The third line encapsulation layer CADa may be a layer formed together with the cathode electrode CAD. The cathode electrode CAD may be formed on the front surface of the lower substrate SUB, and a part of the cathode electrode CAD disposed in the soft area SA may serve as the third line encapsulation layer CADa.

The fourth line encapsulation layer PAS1a is disposed on the third line encapsulation layer CADa. The fourth line encapsulation layer PAS1a may be integrated with the first inorganic encapsulation layer PAS1 of the first encapsulation layer EC1. The first inorganic encapsulation layer PAS1 may extend from the rigid area RA to the soft area SA, thereby defining the fourth line encapsulation layer PAS1a. The material, which constitutes the first inorganic encapsulation layer PAS1, may be formed on the front surface of the lower substrate SUB, such that the first inorganic encapsulation layer PAS1 and the fourth line encapsulation layer PAS1a may be formed together.

The fifth line encapsulation layer PAS2a is disposed on the fourth line encapsulation layer PAS1a. The fifth line encapsulation layer PAS2a may be integrated with the second inorganic encapsulation layer PAS2 of the first encapsulation layer EC1. The second inorganic encapsulation layer PAS2 may extend from the rigid area RA to the soft area SA, thereby defining the fifth line encapsulation layer PAS2a. The material, which constitutes the second inorganic encapsulation layer PAS2, may be formed on the front surface of the lower substrate SUB, such that the second inorganic encapsulation layer PAS2 and the fifth line encapsulation layer PAS2a may be formed together.

The sixth line encapsulation layer PAS3a is disposed on the fifth line encapsulation layer PAS2a. The sixth line encapsulation layer PAS3a may be integrated with the third inorganic encapsulation layer PAS3 of the first encapsulation layer EC1. The third inorganic encapsulation layer PAS3 may extend from the rigid area RA to the soft area SA, thereby defining the sixth line encapsulation layer PAS3a. The material, which constitutes the third inorganic encapsulation layer PAS3, may be formed on the front surface of the lower substrate SUB, such that the third inorganic encapsulation layer PAS3 and the sixth line encapsulation layer PAS3a may be formed together.

Therefore, during the process of forming the light-emitting element LD and the first encapsulation layer EC1, the second line encapsulation layer EMLa, the third line encapsulation layer CADa, the fourth line encapsulation layer PAS1a, the fifth line encapsulation layer PAS2a, and a sixth layer of the second encapsulation layer EC2 may be formed together, such that the process of forming the second encapsulation layer EC2 may be simplified. Further, the second encapsulation layer EC2 disposed in the soft area SA includes the plurality of layers, which may minimize the penetration of moisture and oxygen into the connection line CL.

Further, because the light-emitting layer EML and the cathode electrode CAD of the light-emitting element LD and the first inorganic encapsulation layer PAS1, the second inorganic encapsulation layer PAS2, and the third inorganic encapsulation layer PAS3 of the first encapsulation layer EC1 are formed on the front surface of the lower substrate SUB, the process of patterning the light-emitting element LD and the first encapsulation layer EC1 may be excluded, such that the process of manufacturing the display device 500 may be simplified.

In addition, the fourth line encapsulation layer PAS1a, the fifth line encapsulation layer PAS2a, and the sixth line encapsulation layer PAS3a of the second encapsulation layer EC2 may be formed by continuously extending the first inorganic encapsulation layer PAS1, the second inorganic encapsulation layer PAS2, and the third inorganic encapsulation layer PAS3 of the first encapsulation layer EC1 to the soft area SA, such that the first encapsulation layer EC1 and the second encapsulation layer EC2 may cover the entire front surface of the lower substrate SUB. Therefore, a space, which is not sealed by the first encapsulation layer EC1 and the second encapsulation layer EC2, may be eliminated, and all the constituent elements in the rigid area RA and the soft area SA may be protected from moisture and oxygen.

Meanwhile, with reference to FIG. 6, during the process of forming the first line encapsulation layer P1a of the second encapsulation layer EC2, the fluorine-based residual film FL may be formed on the front surface of the lower substrate SUB. Specifically, the photoresist pattern PR is formed to cover the rigid area RA before the process of forming the light-emitting layer EML or the second line encapsulation layer EMLa. After the anode electrode AND and the bank BNK are formed, the photoresist pattern PR may be formed to cover the rigid area RA. Further, the material, e.g., the polyimide layer PI, which constitutes the first line encapsulation layer P1a of the second encapsulation layer EC2, may be formed on the front surface of the lower substrate SUB. Further, the photoresist pattern PR may be removed by applying the fluorine-based solution onto the front surface of the lower substrate SUB, and a part of the fluorine-based solution is applied onto the front surface of the lower substrate SUB, thereby defining the fluorine-based residual film FL. Therefore, the fluorine-based residual film FL may be formed above the bank BNK, the anode electrode AND exposed from the bank BNK, a side surface of the third planarization layer PNL3, a side surface of the fifth conductive layer SD3, the first connection line CL1, and the first line encapsulation layer P1a. The fluorine-based residual film FL may delay the penetration of moisture and oxygen into a portion below the fluorine-based residual film FL.

In the display device 500 according to another example embodiment of the present disclosure, the components of the light-emitting element LD and the first encapsulation layer EC1 extend to the soft area SA, such that the plurality of layers of the second encapsulation layer EC2 may be easily formed. For example, the second line encapsulation layer EMLa, the third line encapsulation layer CADa, the fourth line encapsulation layer PAS1a, the fifth line encapsulation layer PAS2a, and the sixth line encapsulation layer PAS3a of the second encapsulation layer EC2 may be formed by the same process and made of the same material as the light-emitting layer EML, the cathode electrode CAD, the first inorganic encapsulation layer PAS1, the second inorganic encapsulation layer PAS2, and the third inorganic encapsulation layer PAS3. Therefore, the second encapsulation layer EC2 is formed as the plurality of layers, which may improve the performance of the second encapsulation layer EC2 and simplify the process of forming the second encapsulation layer EC2. In addition, because the first inorganic encapsulation layer PAS1, the second inorganic encapsulation layer PAS2, and the third inorganic encapsulation layer PAS3 of the first encapsulation layer EC1 are integrated with the fourth line encapsulation layer PAS1a, the fifth line encapsulation layer PAS2a, and the sixth line encapsulation layer PAS3a of the second encapsulation layer EC2, a portion, which is not sealed by the first encapsulation layer EC1 and the second encapsulation layer EC2, may be minimized, and a gap between the first encapsulation layer EC1 and the second encapsulation layer EC2 may be removed, which may reduce the penetration of moisture and oxygen.

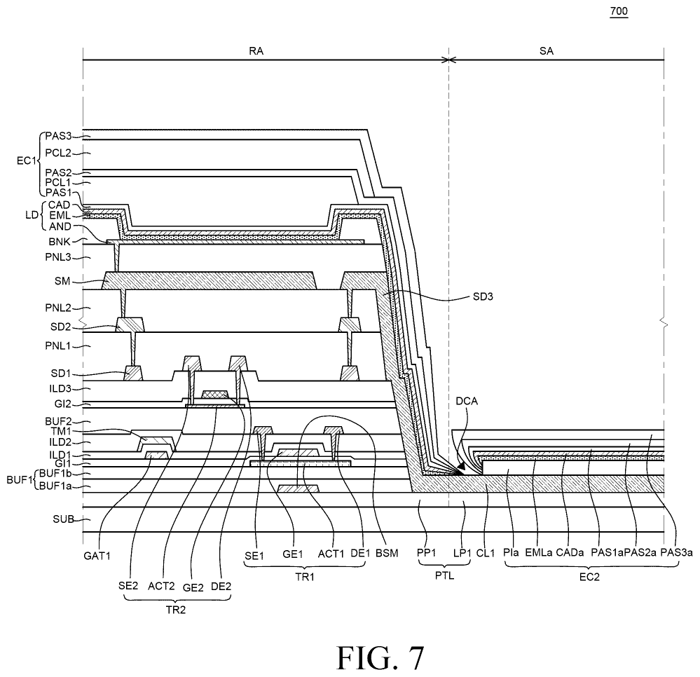

FIG. 7 is a cross-sectional view of a display device according to still another example embodiment of the present disclosure. A display device 700 in FIG. 7 is substantially identical in configuration to the display device 500 in FIGS. 5 and 6, except for the second encapsulation layer EC2. Therefore, repeated descriptions of the identical components will be omitted.

With reference to FIG. 7, at least some of the second line encapsulation layer EMLa, the third line encapsulation layer CADa, the fourth line encapsulation layer PAS1a, the fifth line encapsulation layer PAS2a, and the sixth line encapsulation layer PAS3a of the second encapsulation layer EC2 may be disconnected from the light-emitting element LD and the first encapsulation layer EC1. Some layers of the first encapsulation layer EC1, the light-emitting element LD, and the second encapsulation layer EC2 may be separated from one another in the vicinity of the edge of the first line encapsulation layer P1a of the second encapsulation layer EC2, i.e., a disconnection area DCA of the boundary between the rigid area RA and the soft area SA. The disconnection area DCA may be an area adjacent to an end of the first line encapsulation layer P1a, and the disconnection area DCA may be adjacent to the boundary between the rigid area RA and the soft area SA. For example, the light-emitting layer EML and the second line encapsulation layer EMLa may be separated from each other in the disconnection area DCA in the vicinity of the end of the first line encapsulation layer P1a. The cathode electrode CAD and the third line encapsulation layer CADa may also be separated from each other, the first inorganic encapsulation layer PAS1 and the fourth line encapsulation layer PAS1a may also be separated from each other, the second inorganic encapsulation layer PAS2 and the fifth line encapsulation layer PAS2a may also be separated from each other, and the third inorganic encapsulation layer PAS3 and the sixth line encapsulation layer PAS3a may also be separated from each other in the vicinity of the end of the first line encapsulation layer P1a.

In particular, the cathode electrode CAD of the light-emitting element LD may be separated from the third line encapsulation layer CADa of the second encapsulation layer EC2, such that the light-emitting element LD may emit light only in the rigid area RA. Only the conductive layer, which is formed in the rigid area RA among the conductive layers formed in the soft area SA and the rigid area RA, may substantially serve as the cathode electrode CAD, such that light may be emitted only in the rigid area RA.

In this case, at least some of the second line encapsulation layer EMLa, the third line encapsulation layer CADa, the fourth line encapsulation layer PAS1a, the fifth line encapsulation layer PAS2a, and the sixth line encapsulation layer PAS3a of the second encapsulation layer EC2 may be disconnected by a thickness of the first line encapsulation layer P1a and a shape of the end of the first line encapsulation layer P1a. For example, a level difference between the first line encapsulation layer P1a and the connection line CL increases as the thickness of the first line encapsulation layer P1a increases. Therefore, the second line encapsulation layer EMLa, the third line encapsulation layer CADa, the fourth line encapsulation layer PAS1a, the fifth line encapsulation layer PAS2a, and the sixth line encapsulation layer PAS3a of the second encapsulation layer EC2 may be easily disconnected at the end of the first line encapsulation layer P1a. In addition, in case that an inclination of the end of the first line encapsulation layer P1a has an inversely tapered shape, the second line encapsulation layer EMLa, the third line encapsulation layer CADa, the fourth line encapsulation layer PAS1a, the fifth line encapsulation layer PAS2a, and the sixth line encapsulation layer PAS3a of the second encapsulation layer EC2 may be easily disconnected at the end of the first line encapsulation layer P1a having an inversely tapered shape. Therefore, the remaining components of the second encapsulation layer EC2 may be disconnected by adjusting the thickness of the first line encapsulation layer P1a and designing the end of the first line encapsulation layer P1a in an inversely tapered shape.

Further, in the disconnection area DCA, the first inorganic encapsulation layer PAS1, the second inorganic encapsulation layer PAS2, and the third inorganic encapsulation layer PAS3 may be disposed to cover the end of the light-emitting layer EML and the end of the cathode electrode CAD. Therefore, the exposure of the light-emitting layer EML to the outside may be minimized even though the second encapsulation layer EC2 and the first encapsulation layer EC1 are disconnected from each other in the disconnection area DCA, such that the light-emitting element LD may be easily protected from moisture and oxygen.

Meanwhile, like the display device 500 in FIG. 5, the display device 700 in FIG. 7 may also be configured such that the fluorine-based residual film FL may be entirely formed in the rigid area RA and the soft area SA during the process of forming the first line encapsulation layer P1a. For example, in the rigid area RA, the fluorine-based residual film FL may be formed on a bottom surface of the light-emitting layer EML, such as a portion between the light-emitting layer EML and the anode electrode AND, a portion between the light-emitting layer EML and the bank BNK, and a portion between the light-emitting layer EML and the fifth conductive layer SD3. In the soft area SA, the fluorine-based residual film FL may be formed between the first line encapsulation layer P1a and the second line encapsulation layer EMLa. The fluorine-based residual film FL may protect the other components by minimizing the penetration of moisture or the like into the other components below the fluorine-based residual film FL, such that the reliability of the display device 700 in FIG. 7 may be improved.

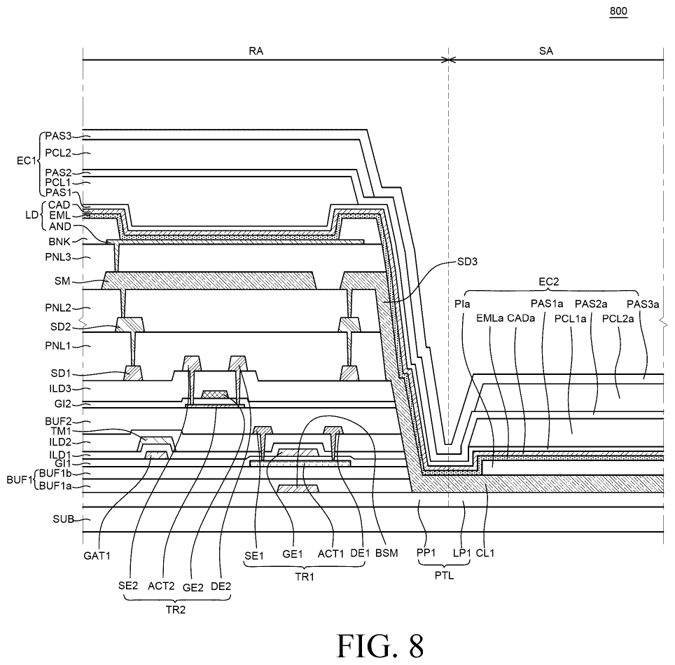

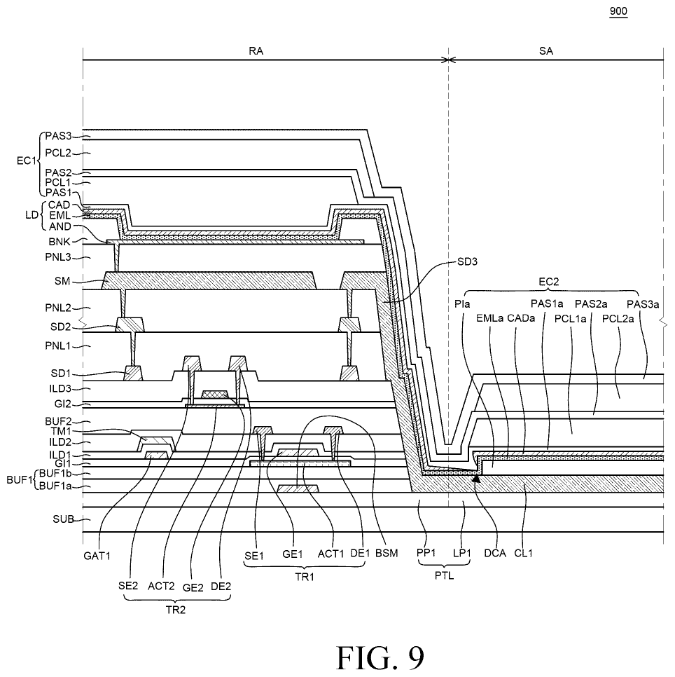

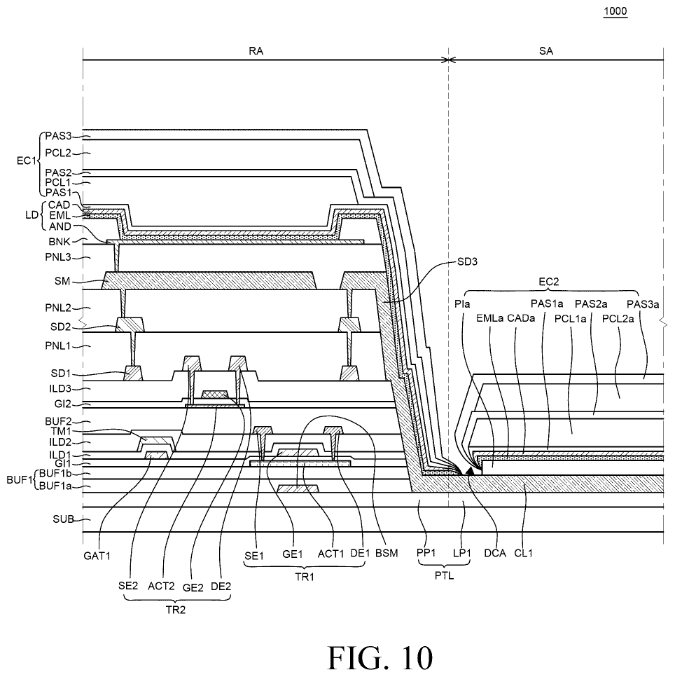

FIG. 8 is a cross-sectional view of a display device according to yet another example embodiment of the present disclosure. FIG. 9 is a cross-sectional view of a display device according to still yet another example embodiment of the present disclosure. FIG. 10 is a cross-sectional view of a display device according to a further example embodiment of the present disclosure. Display devices 800, 900, and 1000 in FIGS. 8 to 10 are substantially identical in configuration to the display device 500 illustrated in FIGS. 5 and 6, except that the second encapsulation layer EC2 further includes a seventh line encapsulation layer PCL1a and an eighth line encapsulation layer PCL2a. Therefore, repeated descriptions of the identical components will be omitted.

With reference to FIGS. 8 to 10, the second encapsulation layer EC2 may include a plurality of layers and, for example, include the first line encapsulation layer P1a, the second line encapsulation layer EMLa, the third line encapsulation layer CADa, the fourth line encapsulation layer PAS1a, the fifth line encapsulation layer PAS2a, the sixth line encapsulation layer PAS3a, the seventh line encapsulation layer PCL1a, and the eighth line encapsulation layer PCL2a.

In the soft area SA, the seventh line encapsulation layer PCL1a is disposed between the fourth line encapsulation layer PAS1a and the fifth line encapsulation layer PAS2a. The seventh line encapsulation layer PCL1a may be formed by the same process as the first organic encapsulation layer PCL1. The seventh line encapsulation layer PCL1a may fill cracks in the fourth line encapsulation layer PAS1a or cover particles formed on the fourth line encapsulation layer PAS1a. The fourth line encapsulation layer PAS1a, the seventh line encapsulation layer PCL1a, and the fifth line encapsulation layer PAS2a may be formed by sequentially performing a process of forming the first inorganic encapsulation layer PAS1 and the fourth line encapsulation layer PAS1a, a process of forming the first organic encapsulation layer PCL1 and the seventh line encapsulation layer PCL1a, and a process of forming the second inorganic encapsulation layer PAS2 and the fifth line encapsulation layer PAS2a.

In the soft area SA, the eighth line encapsulation layer PCL2a is disposed between the fifth line encapsulation layer PAS2a and the sixth line encapsulation layer PAS3a. The eighth line encapsulation layer PCL2a may be formed by the same process as the second organic encapsulation layer PCL2. The eighth line encapsulation layer PCL2a may fill cracks in the fifth line encapsulation layer PAS2a or cover particles formed on the fifth line encapsulation layer PAS2a. The fifth line encapsulation layer PAS2a, the eighth line encapsulation layer PCL2a, and the sixth line encapsulation layer PAS3a may be formed by sequentially performing a process of forming the second inorganic encapsulation layer PAS2 and the fifth line encapsulation layer PAS2a, a process of forming the second organic encapsulation layer PCL2 and the eighth line encapsulation layer PCL2a, and a process of forming the third inorganic encapsulation layer PAS3 and the sixth line encapsulation layer PAS3a.

The light-emitting layer EML, the cathode electrode CAD, and the first encapsulation layer EC1 in the rigid area RA and the second to eighth line encapsulation layers EMLa, CADa, PAS1a, PAS2a, PAS3a, PCL1a, and PCL2a of the second encapsulation layer EC2 in the soft area SA are formed by the same process, such that the second encapsulation layer EC2 may be more easily formed. In addition, because the second encapsulation layer EC2 includes the plurality of layers including the first to eighth line encapsulation layers P1a, EMLa, CADa, PAS1a, PAS2a, PAS3a, PCL1a, and PCL2a, the penetration of moisture and oxygen into the connection line CL from the second encapsulation layer EC2 may be minimized.

In this case, layers, which are formed in common on the light-emitting layer EML, the cathode electrode CAD, and the first encapsulation layer EC1 in the rigid area RA and the second encapsulation layer EC2 in the soft area SA, may be connected to and integrated with one another, and at least some of the layers formed in common may be separated from one another in the disconnection area DCA.

With reference to FIG. 8, some components of the light-emitting layer EML, the cathode electrode CAD, and the first encapsulation layer EC1 and some components of the second encapsulation layer EC2 may be connected to and integrated with one another. For example, the light-emitting layer EML and the second line encapsulation layer EMLa may be connected to and integrated with each other, the cathode electrode CAD and the third line encapsulation layer CADa may be connected to and integrated with each other, the first inorganic encapsulation layer PAS1 and the fourth line encapsulation layer PAS1a may be connected to and integrated with each other, the second inorganic encapsulation layer PAS2 and the fifth line encapsulation layer PAS2a may be connected to and integrated with each other, and the third inorganic encapsulation layer PAS3 and the sixth line encapsulation layer PAS3a may be connected to and integrated with each other.

With reference to FIG. 9, some components of the light-emitting layer EML and the first encapsulation layer EC1 and some components of the second encapsulation layer EC2 may be connected to and integrated with one another. For example, the light-emitting layer EML and the second line encapsulation layer EMLa may be connected to and integrated with each other, the first inorganic encapsulation layer PAS1 and the fourth line encapsulation layer PAS1a may be connected to and integrated with each other, the second inorganic encapsulation layer PAS2 and the fifth line encapsulation layer PAS2a may be connected to and integrated with each other, and the third inorganic encapsulation layer PAS3 and the sixth line encapsulation layer PAS3a may be connected to and integrated with each other. Further, the cathode electrode CAD and the third line encapsulation layer CADa may be separated from each other in the disconnection area DCA. The cathode electrode CAD may be formed to be separated from the third line encapsulation layer CADa, such that only the conductive layer disposed in the rigid area RA may serve as the cathode electrode CAD, and light may be emitted in the rigid area RA.

With reference to FIG. 10, the second encapsulation layer EC2 may be formed to be separated from the components in the rigid area RA. Some components of the second encapsulation layer EC2, which is formed together with the light-emitting layer EML, the cathode electrode CAD, and the first encapsulation layer EC1, may be separated from the light-emitting layer EML, the cathode electrode CAD, and the first encapsulation layer EC1 in the disconnection area DCA. For example, in the disconnection area DCA, the light-emitting layer EML and the second line encapsulation layer EMLa may be separated from each other, the cathode electrode CAD and the third line encapsulation layer CADa may be separated from each other, the first inorganic encapsulation layer PAS1 and the fourth line encapsulation layer PAS1a may be separated from each other, the second inorganic encapsulation layer PAS2 and the fifth line encapsulation layer PAS2a may be separated from each other, and the third inorganic encapsulation layer PAS3 and the sixth line encapsulation layer PAS3a may be separated from each other.

Further, with reference to FIGS. 9 and 10 together, some components of the second encapsulation layer EC2 may be formed to be separated from the components in the rigid area RA in the disconnection area DCA by adjusting the thickness of the first line encapsulation layer P1a of the second encapsulation layer EC2 and adjusting the shape of the end of the first line encapsulation layer P1a of the second encapsulation layer EC2. For example, the first line encapsulation layer P1a is formed to have a large thickness, such that at least some of the second to eighth line encapsulation layers EMLa, CADa, PAS1a, PAS2a, PAS3a, PCL1a, and PCL2a of the second encapsulation layer EC2 may be disconnected from the components in the rigid area RA. For example, the end of the first line encapsulation layer P1a positioned in the disconnection area DCA is formed in an inversely tapered shape, such that at least some of the second to eighth line encapsulation layers EMLa, CADa, PAS1a, PAS2a, PAS3a, PCL1a, and PCL2a of the second encapsulation layer EC2 may be disconnected from the components in the rigid area RA.

Meanwhile, like the display devices 500 and 800 in FIGS. 5 and 8, all the display devices 800, 900, and 1000 in FIGS. 8 to 10 may each include the fluorine-based residual film FL formed during the process of forming the first line encapsulation layer P1a. For example, in the rigid area RA, the fluorine-based residual film FL may be formed on the bottom surface of the light-emitting layer EML, such as the portion between the light-emitting layer EML and the anode electrode AND, the portion between the light-emitting layer EML and the bank BNK, and the portion between the light-emitting layer EML and the fifth conductive layer SD3. In the soft area SA, the fluorine-based residual film FL may be formed between the first line encapsulation layer P1a and the second line encapsulation layer EMLa. The fluorine-based residual film FL may protect the other components by minimizing the penetration of moisture or the like into the other components below the fluorine-based residual film FL, such that the reliability of the display devices 800, 900, and 1000 in FIGS. 8 to 10 may be improved.

Therefore, in the display devices 800, 900, and 1000 according to another example embodiment of the present disclosure, some layers of the second encapsulation layer EC2 are formed by the same process as the light-emitting element LD and the first encapsulation layer EC1, which may simplify the process of forming the second encapsulation layer EC2. For example, the second line encapsulation layer EMLa and the third line encapsulation layer CADa of the second encapsulation layer EC2 may be formed together at the time of forming the light-emitting layer EML and the cathode electrode CAD of the light-emitting element LD. The fourth to eighth line encapsulation layers PAS1a, PAS2a, PAS3a, PCL1a, and PCL2a of the second encapsulation layer EC2 may be formed together at the time of forming the first inorganic encapsulation layer PAS1, the first organic encapsulation layer PCL1, the second inorganic encapsulation layer PAS2, the second organic encapsulation layer PCL2, and the third inorganic encapsulation layer PAS3 of the first encapsulation layer EC1. Therefore, it is possible to easily form the second encapsulation layer EC2 as the plurality of layers while simplifying the process of forming the second encapsulation layer EC2.

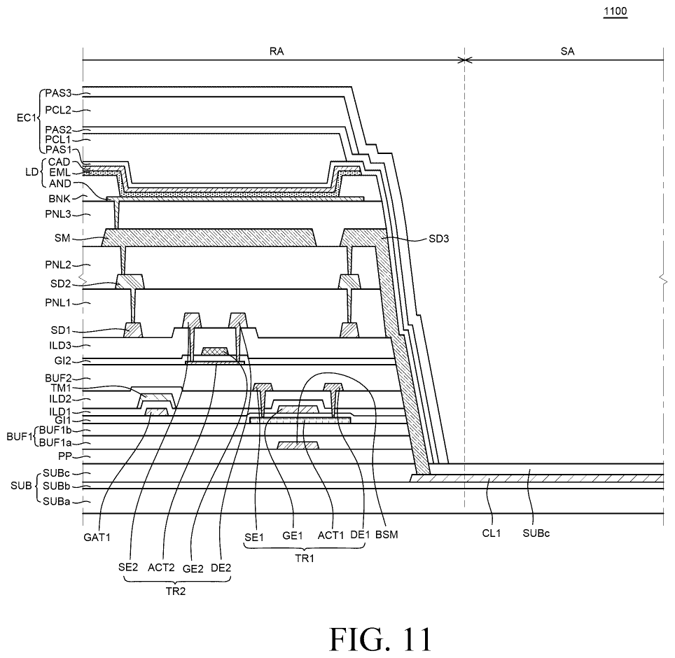

FIG. 11 is a cross-sectional view of a display device according to another further example embodiment of the present disclosure. A display device 1100 in FIG. 11 is substantially identical in configuration to the display device 100 in FIGS. 1 to 4, except for the lower substrate SUB, the pattern layer PTL, and the connection line CL. Therefore, repeated descriptions of the identical components will be omitted.

With reference to FIG. 11, the lower substrate SUB includes a first lower substrate SUBa, a second lower substrate SUBb, and a third lower substrate SUBc. The second lower substrate SUBb is disposed on the first lower substrate SUBa, and the third lower substrate SUBc is disposed on the second lower substrate SUBb.

The first lower substrate SUBa and the third lower substrate SUBc may be substrates configured to support the components formed on the lower substrate SUB. The first lower substrate SUBa and the third lower substrate SUBc may be flexible substrates made of a plastic material. In this case, the flexibility may be interpreted in the same way as bendable, unbreakable, rollable, and foldable properties and the like.

For example, the first lower substrate SUBa and the third lower substrate SUBc may include plastic. In this case, the first lower substrate SUBa and the third lower substrate SUBc may be referred to as plastic films or plastic substrates. For example, the first lower substrate SUBa and the third lower substrate SUBc may include at least one selected from a group consisting of polyester-based polymer, silicon-based polymer, acrylic-based polymer, polyolefin-based polymer, and a polymer thereof. For example, the first lower substrate SUBa and the third lower substrate SUBc may be polyimide substrates made of polyimide (PI).

The second lower substrate SUBb may include an inorganic insulating material. The second lower substrate SUBb may be an inorganic film formed between the first lower substrate SUBa and the third lower substrate SUBc. For example, the second lower substrate SUBb may be configured as a single layer or multilayer made of silicon nitride (SiNx) or silicon oxide (SiOx). However, the present disclosure is not limited thereto.

Meanwhile, in case that the lower substrate SUB includes polyimide, moisture may pass through the substrate made of polyimide and penetrate into the thin-film transistor or the like included in the pixel PX, which may degrade the reliability of the pixel PX and degrade the performance of the display device 1100.

Therefore, the lower substrate SUB may include a dual polyimide substrate, i.e., the first lower substrate SUBa and the third lower substrate SUBc. Further, in order to suppress the penetration of moisture, the lower substrate SUB may be configured such that the second lower substrate SUBb made of an inorganic material may be further disposed between the first lower substrate SUBa and the third lower substrate SUBc that are polyimide substrates. Therefore, the second lower substrate SUBb may be formed to inhibit moisture from being introduced into the display device 1100 through the first lower substrate SUBa and the third lower substrate SUBc, which are polyimide substrates, thereby further improving the performance and reliability of the product. In addition, because the second lower substrate SUBb, which is an inorganic film, is formed between the first lower substrate SUBa and the third lower substrate SUBc that are polyimide substrates, electric charges charged on the polyimide substrate may be blocked, which may further improve the reliability of the product.

Further, the pattern layer PTL may include only the plurality of plate patterns PP. The pattern layer PTL may include the plurality of first plate patterns PP1 and the plurality of second plate patterns PP2. Further, instead of the plurality of line patterns LP, the lower substrate SUB may support and protect the plurality of connection lines CL in the soft area SA.

Specifically, the plurality of connection lines CL may be disposed in the lower substrate SUB instead of being disposed on the plurality of line patterns LP. The plurality of connection lines CL may be disposed between the first lower substrate SUBa and the third lower substrate SUBc. For example, the plurality of connection lines CL may be disposed between the second lower substrate SUBb and the third lower substrate SUBc. Further, the plurality of connection lines CL may also be disposed between the first lower substrate SUBa and the second lower substrate SUBb. In this case, the third lower substrate SUBc and the first lower substrate SUBa may serve as encapsulation layers for protecting the plurality of connection lines CL from outside moisture and oxygen. In particular, the third lower substrate SUBc may be disposed to cover the upper portion of the connection line CL and protect the connection line CL from moisture and oxygen.

Further, the fifth conductive layer SD3, which extends from the rigid area RA toward the connection line CL, may be electrically connected to the plurality of connection lines CL through a contact hole formed in the third lower substrate SUBc. In this case, in a state in which the second planarization layer PNL2 is formed, a contact hole, through which the fifth conductive layer SD3 and the connection line CL are connected to the third lower substrate SUBc, may be formed. Further, after the contact hole is formed, the fifth conductive layer SD3 and the second shield pattern SM may be formed together. The fifth conductive layer SD3 may be formed into the contact hole of the third lower substrate SUBc and connected to the connection line CL. Further, the third planarization layer PNL3, the bank BNK, the light-emitting element LD, and the first encapsulation layer EC1 are sequentially formed on the fifth conductive layer SD3, such that the display device 1100 in FIG. 11 may be formed.

In this case, the first inorganic encapsulation layer PAS1, the second inorganic encapsulation layer PAS2, and the third inorganic encapsulation layer PAS3 of the first encapsulation layer EC1 may extend to adjoin a top surface of the third lower substrate SUBc, thereby sealing all the components in the rigid area RA. The first inorganic encapsulation layer PAS1, the second inorganic encapsulation layer PAS2, and the third inorganic encapsulation layer PAS3 may extend from the rigid area RA to the soft area SA and adjoin the top surface of the third lower substrate SUBc. In particular, the first inorganic encapsulation layer PAS1, the second inorganic encapsulation layer PAS2, and the third inorganic encapsulation layer PAS3 may extend toward the third lower substrate SUBc and cover the entire fifth conductive layer SD3, and the fifth conductive layer SD3 may be sealed without being exposed to the outside. Therefore, the components in the rigid area RA may be sealed in spaces between the first inorganic encapsulation layer PAS1, the second inorganic encapsulation layer PAS2, the third inorganic encapsulation layer PAS3, and the third lower substrate SUBc and inhibited from being damaged by moisture and oxygen.

Therefore, in the display device 1100 according to another further example embodiment of the present disclosure, the connection line CL may be disposed between the first lower substrate SUBa and the third lower substrate SUBc, and the third lower substrate SUBc may be used as an encapsulation layer for protecting the connection line CL. The third lower substrate SUBc may be disposed to cover all the connection lines CL and protect the connection lines CL so that the connection lines CL are not exposed to moisture and oxygen. Therefore, because it is not necessary to form a separate encapsulation layer for protecting the connection line CL in the soft area SA, it is possible to simplify the structure of the display device 1100. In addition, because the fifth conductive layer SD3 and the connection line CL are connected through the contact hole formed in the third lower substrate SUBc, the fifth conductive layer SD3 or the connection line CL may not be exposed to the outside.

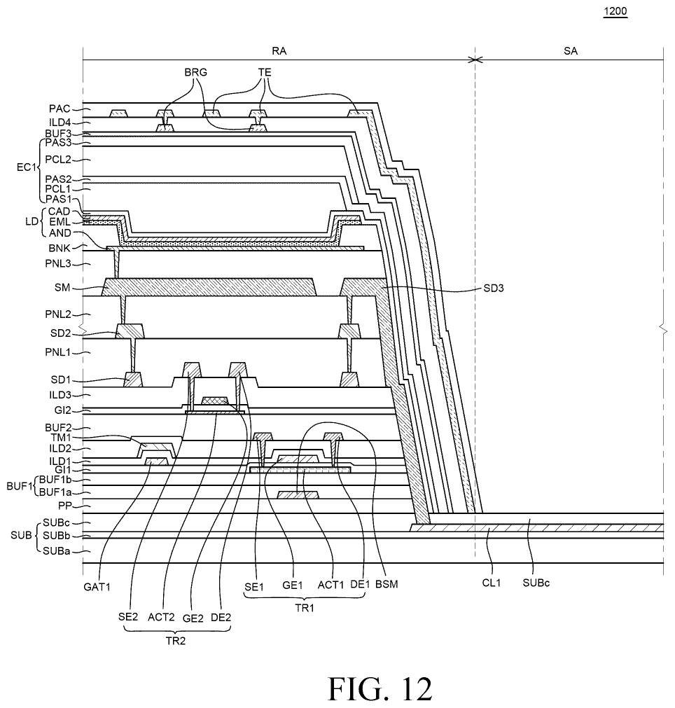

FIG. 12 is a cross-sectional view of a display device according to still another further example embodiment of the present disclosure. A display device 1200 in FIG. 12 is substantially identical in configuration to the display device 1100 in FIG. 11, except that the display device 1200 further includes a plurality of touch electrodes TE, a plurality of bridge electrodes BRG, a third buffer layer BUF3, a fourth interlayer insulation layer ILD4, and a protective layer PAC. Therefore, repeated descriptions of the identical components will be omitted.

With reference to FIG. 12, a touch sensor is disposed on the first encapsulation layer EC1 in the rigid area RA. The touch sensor may sense a touch input applied from the outside by a user's finger, a touch pen, or the like. The touch sensor includes the plurality of touch electrodes TE, the plurality of bridge electrodes BRG, the third buffer layer BUF3, the fourth interlayer insulation layer ILD4, and the protective layer PAC.

First, the third buffer layer BUF3 is disposed on the first encapsulation layer EC1. The third buffer layer BUF3 is an insulation layer for protecting surrounding components, such as the first encapsulation layer EC1, the light-emitting element LD, the touch electrode TE, and the bridge electrode BRG, during a process of forming the touch sensor. For example, the third buffer layer BUF3 may minimize a degree to which moisture or a solution, which is used for a process related to the touch sensor, penetrates from the outside into the light-emitting layer EML of the light-emitting element LD. In addition, the third buffer layer BUF3 may protect the first encapsulation layer EC1 so that the first encapsulation layer EC1 is not damaged when the display device 1200 is stretched and deformed. The third buffer layer BUF3 may protect the touch electrode TE or the bridge electrode BRG of the touch sensor so that the touch electrode TE or the bridge electrode BRG does not crack when the display device 1200 is stretched and deformed.

In order to suppress damage to the light-emitting layer EML vulnerable to a high-temperature process, the third buffer layer BUF3 may be made of an insulating material that may be formed by a low-temperature process. For example, the third buffer layer BUF3 may be made of at least any one of acrylic-based materials, epoxy-based materials, and siloxane-based materials.

The fourth interlayer insulation layer ILD4 is disposed on the third buffer layer BUF3. The fourth interlayer insulation layer ILD4 may be disposed between the plurality of bridge electrodes BRG and the plurality of touch electrodes TE and insulate some of the bridge electrodes BRG and some of the touch electrodes TE. The fourth interlayer insulation layer ILD4 may be configured as a single layer or multilayer made of silicon nitride (SiNx) or silicon oxide (SiOx). However, the present disclosure is not limited thereto.

The plurality of touch electrodes TE is disposed on the fourth interlayer insulation layer ILD4. The plurality of touch electrodes TE may be used to sense touch inputs in various ways. For example, in case that the touch sensor senses a touch input by using mutual capacitance, the plurality of touch electrodes TE of the plurality of touch sensors may include a driving electrode to which a touch driving signal is applied, and a sensing electrode configured to generate capacitance the driving electrode. Further, the touch input may be sensed on the basis of a change in capacitance between the driving electrode and the sensing electrode. As another example, in case that the touch sensor senses a touch input in a self-capacitance manner, the plurality of touch electrodes TE of the touch sensor may serve as driving electrodes or sensing electrodes. Further, a touch driving signal may be applied to the touch electrode TE, and a touch input may be sensed on the basis of a change in capacitance of the touch electrode TE in accordance with the presence or absence of a touch. The touch sensing method of the touch sensor is proposed for illustrative purposes only, and the touch electrode TE may be used in various ways in accordance with the touch sensing method of the touch sensor. However, the present disclosure is not limited thereto.

Further, the plurality of touch electrodes TE may have a mesh structure. The light emitted from the light-emitting element LD may propagate to the outside through opening portions of the mesh structure of the plurality of touch electrodes TE. Further, because the plurality of touch electrodes TE has the mesh structure, parasitic capacitance with other electrodes around the touch electrode TE may be reduced. In addition, because the plurality of touch electrodes TE has the mesh structure, the plurality of touch electrodes TE may have high flexibility.

The plurality of bridge electrodes BRG is disposed between the fourth interlayer insulation layer ILD4 and the third buffer layer BUF3. The plurality of touch electrodes TE may be connected to each other through the plurality of bridge electrodes BRG. For example, some of the plurality of touch electrodes TE may be connected to the bridge electrode BRG through contact holes of the fourth interlayer insulation layer ILD4. Further, the bridge electrode BRG may also be connected to another touch electrode TE. The two touch electrodes TE may be electrically connected to each other through the bridge electrode BRG.

The plurality of touch electrodes TE and the plurality of bridge electrodes BRG may each be configured as a layered structure made of a metallic material such as copper (Cu), aluminum (Al), titanium (Ti), chromium (Cr), and nickel (Ni) or a metallic material such as titanium/aluminum/titanium (Ti/Al/Ti). However, the present disclosure is not limited thereto.

Meanwhile, although not illustrated in the drawings, the plurality of touch electrodes TE may be electrically connected to the touch electrode TE in the adjacent rigid area RA through any one of the plurality of connection lines CL. For example, one of the plurality of touch electrodes TE may extend to the top surface of the third lower substrate SUBc adjacent to the soft area SA along a top surface of the fourth interlayer insulation layer ILD4 disposed on the upper portion and lateral portion of the light-emitting element LD. Further, the touch electrode TE may be electrically connected to any one of the connection lines CL, which are disposed between the third lower substrate SUBc and the second lower substrate SUBb, through the contact hole formed in the third lower substrate SUBc.

Next, the protective layer PAC is disposed on the plurality of touch electrodes TE. The protective layer PAC may be disposed to cover all the plurality of touch electrodes TE and the fourth interlayer insulation layer ILD4 and protect the plurality of touch electrodes TE and the fourth interlayer insulation layer ILD4. For example, the protective layer PAC may be an organic insulation film made of a material such as epoxy-based polymer or acrylic-based polymer. In addition, the protective layer PAC may include an inorganic material silicon nitride (SiNx) or silicon oxide (SiOx). However, the present disclosure is not limited thereto.

Meanwhile, the insulation layers, e.g., the third buffer layer BUF3, the fourth interlayer insulation layer ILD4, and the protective layer PAC included in the touch sensor may extend from the upper portion of the first encapsulation layer EC1 to the top surface of the third lower substrate SUBc adjacent to the soft area SA. Therefore, the third buffer layer BUF3, the fourth interlayer insulation layer ILD4, and the protective layer PAC may seal the components in the rigid area RA together with the first inorganic encapsulation layer PAS1, the second inorganic encapsulation layer PAS2, and the third inorganic encapsulation layer PAS3 of the first encapsulation layer EC1. The third buffer layer BUF3, the fourth interlayer insulation layer ILD4, the protective layer PAC, the first inorganic encapsulation layer PAS1, the second inorganic encapsulation layer PAS2, and the third inorganic encapsulation layer PAS3 may extend from the rigid area RA toward the soft area SA and adjoin the top surface of the third lower substrate SUBc. In this case, all the connection portions between the connection line CL and the fifth conductive layer SD3 may be sealed by the third buffer layer BUF3, the fourth interlayer insulation layer ILD4, the protective layer PAC, the first inorganic encapsulation layer PAS1, the second inorganic encapsulation layer PAS2, and the third inorganic encapsulation layer PAS3, such that the penetration of moisture and oxygen into the fifth conductive layer SD3 and the connection line CL may be minimized.

Meanwhile, the touch sensor in FIG. 12 may be applied to the display devices 100, 500, 700, 8000, 900, and 1000 in FIGS. 1 to 10 in addition to the display device 1100 in FIG. 11. For example, in case that the touch sensor in FIG. 12 is applied to the display device 100 in FIGS. 1 to 4, the third buffer layer BUF3, the fourth interlayer insulation layer ILD4, and the protective layer PAC of the touch sensor may extend toward the soft area SA and cover a part of the connection line CL together with the first inorganic encapsulation layer PAS1, the second inorganic encapsulation layer PAS2, and the third inorganic encapsulation layer PAS3. As another example, in case that the touch sensor in FIG. 12 is applied to each of the display device 500 in FIG. 5, the display device 700 in FIG. 7, the display device 800 in FIG. 8, the display device 900 in FIG. 9, and the display device 1000 in FIG. 10, at least any one of the third buffer layer BUF3, the fourth interlayer insulation layer ILD4, and the protective layer PAC of the touch sensor may be disposed to the soft area SA, and a part of the insulation layer disposed in the soft area SA, together with the second encapsulation layer EC2, may serve as a line encapsulation layer for protecting the connection line CL.

Therefore, in the display device 1200 according to still another further example embodiment of the present disclosure, the insulation layers of the touch sensor may be disposed to cover the top surface of the third lower substrate SUBc, thereby protecting the fifth conductive layer SD3 and the connection line CL. For example, the touch sensor may include insulation layers such as the third buffer layer BUF3, the fourth interlayer insulation layer ILD4, and the protective layer PAC. Further, like the first inorganic encapsulation layer PAS1, the second inorganic encapsulation layer PAS2, and the third inorganic encapsulation layer PAS3 of the first encapsulation layer EC1, the third buffer layer BUF3, the fourth interlayer insulation layer ILD4, and the protective layer PAC of the touch sensor may also extend from the rigid area RA toward the soft area SA and seal the components in the rigid area RA. Therefore, in the structure in which the touch sensor is disposed on the first encapsulation layer EC1, the insulation layers of the touch sensor may also extend to seal the components in the rigid area RA, which may improve the reliability of the display device 1200.

Various examples and aspects of the present disclosure are described below. These are provided as examples, and do not limit the scope of the present disclosure.

According to an aspect of the present disclosure, a display device includes a stretchable lower substrate, a plurality of plate patterns disposed on the stretchable lower substrate and spaced apart from one another, a plurality of light-emitting elements disposed on the plurality of plate patterns, a plurality of stretchable connection lines disposed between the plurality of plate patterns, a first encapsulation layer configured to cover the plurality of light-emitting elements, and a second encapsulation layer configured to cover the plurality of stretchable connection lines.

In one or more examples, a plurality of stretchable connection lines may refer to or may include a plurality of connection lines CL or some of the foregoing. In one or more examples, a plurality of stretchable connection lines may refer to or may include a plurality of connection lines CL, first connection lines CL1, or second connection lines CL2, or one or more portions of any of the foregoing.

The first encapsulation layer and the second encapsulation layer may be made of different materials.

The second encapsulation layer may include a polyimide layer.

The display device may further include a fluorine-based residual film disposed on the first encapsulation layer and the second encapsulation layer.

Each of the plurality of light-emitting elements may include an anode electrode, a light-emitting layer disposed on the anode electrode, and a cathode electrode disposed on the light-emitting layer. The first encapsulation layer may include a first inorganic encapsulation layer disposed on the cathode electrode, a first organic encapsulation layer disposed on the first inorganic encapsulation layer, a second inorganic encapsulation layer disposed on the first organic encapsulation layer, a second organic encapsulation layer disposed on the second inorganic encapsulation layer, and a third inorganic encapsulation layer disposed on the second organic encapsulation layer.

The second encapsulation layer may include a first line encapsulation layer configured to adjoin each of the plurality of stretchable connection lines, a second line encapsulation layer disposed on the first line encapsulation layer, disposed on a same layer as the light-emitting layer, and made of a same material as the light-emitting layer, a third line encapsulation layer disposed on the second line encapsulation layer, disposed on a same layer as the cathode electrode, and made of a same material as the cathode electrode, a fourth line encapsulation layer disposed on the third line encapsulation layer, disposed on a same layer as the first inorganic encapsulation layer, and made of a same material as the first inorganic encapsulation layer, a fifth line encapsulation layer disposed on the fourth line encapsulation layer, disposed on a same layer as the second inorganic encapsulation layer, and made of a same material as the second inorganic encapsulation layer, and a sixth line encapsulation layer disposed on the fifth line encapsulation layer, disposed on a same layer as the third inorganic encapsulation layer, and made of a same material as the third inorganic encapsulation layer.

The light-emitting layer, the cathode electrode, the first inorganic encapsulation layer, the second inorganic encapsulation layer, and the third inorganic encapsulation layer may be respectively connected to the second line encapsulation layer, the third line encapsulation layer, the fourth line encapsulation layer, the fifth line encapsulation layer, and the sixth line encapsulation layer.

At least some of the light-emitting layer, the cathode electrode, the first inorganic encapsulation layer, the second inorganic encapsulation layer, and the third inorganic encapsulation layer may be respectively connected to the second line encapsulation layer, the third line encapsulation layer, the fourth line encapsulation layer, the fifth line encapsulation layer, and the sixth line encapsulation layer, and at least some of the light-emitting layer, the cathode electrode, the first inorganic encapsulation layer, the second inorganic encapsulation layer, and the third inorganic encapsulation layer may be respectively separated from the second line encapsulation layer, the third line encapsulation layer, the fourth line encapsulation layer, the fifth line encapsulation layer, and the sixth line encapsulation layer.

The light-emitting layer, the first inorganic encapsulation layer, the second inorganic encapsulation layer, and the third inorganic encapsulation layer may be respectively connected to the second line encapsulation layer, the fourth line encapsulation layer, the fifth line encapsulation layer, and the sixth line encapsulation layer, and the cathode electrode may be separated from the third line encapsulation layer.

The light-emitting layer, the cathode electrode, the first inorganic encapsulation layer, the second inorganic encapsulation layer, and the third inorganic encapsulation layer may be respectively separated from the second line encapsulation layer, the third line encapsulation layer, the fourth line encapsulation layer, the fifth line encapsulation layer, and the sixth line encapsulation layer.

The second encapsulation layer may further include a seventh line encapsulation layer disposed between the fourth line encapsulation layer and the fifth line encapsulation layer, disposed on the same layer as the first organic encapsulation layer, and made of the same material as the first organic encapsulation layer, and a seventh line encapsulation layer disposed between the fifth line encapsulation layer and the sixth line encapsulation layer, disposed on the same layer as the second organic encapsulation layer, and made of the same material as the second organic encapsulation layer.

The seventh line encapsulation layer and the eighth line encapsulation layer may be disposed to overlap an area, in which the plurality of stretchable connection lines is disposed, and spaced apart from the first organic encapsulation layer and the second organic encapsulation layer.

The display device may further include a fluorine-based residual film disposed between the anode electrode and the light-emitting layer and between the first line encapsulation layer and the second line encapsulation layer.

The display device may further include a conductive layer disposed between the plurality of plate patterns and the plurality of light-emitting elements. The conductive layer may extend toward an area between the plurality of plate patterns and may be connected to the plurality of stretchable connection lines, and the first inorganic encapsulation layer, the second inorganic encapsulation layer, and the third inorganic encapsulation layer may be disposed to cover the conductive layer.

The stretchable lower substrate may include a first lower substrate made of polyimide, a second lower substrate disposed on the first lower substrate and made of an inorganic material, and a third lower substrate disposed on the second lower substrate and made of polyimide. The plurality of stretchable connection lines may be disposed between the first lower substrate and the third lower substrate, and the conductive layer may be connected to the plurality of stretchable connection lines through a contact hole of the third lower substrate.

Although the example embodiments of the present disclosure have been described in detail with reference to the accompanying drawings, the present disclosure is not limited thereto and may be embodied in many different forms without departing from the technical concepts of the present disclosure. Therefore, the example embodiments of the present disclosure are provided for illustrative purposes only but not intended to limit the technical concepts of the present disclosure. The scope of the technical concepts of the present disclosure are not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a stretchable lower substrate;
a plurality of plate patterns disposed on the stretchable lower substrate and spaced apart from one another;
a plurality of light-emitting elements disposed on the plurality of plate patterns;
a plurality of stretchable connection lines disposed between the plurality of plate patterns;
a first encapsulation layer configured to cover the plurality of light-emitting elements; and
a second encapsulation layer configured to cover the plurality of stretchable connection lines.

2. The display device of claim 1, wherein the first encapsulation layer and the second encapsulation layer are made of different materials.

3. The display device of claim 2, wherein the second encapsulation layer includes a polyimide layer.

4. The display device of claim 1, further comprising:
a fluorine-based residual film disposed on the first encapsulation layer and the second encapsulation layer.

5. The display device of claim 1, wherein each of the plurality of light-emitting elements comprises:
an anode electrode;
a light-emitting layer disposed on the anode electrode; and
a cathode electrode disposed on the light-emitting layer, and
wherein the first encapsulation layer comprises:
a first inorganic encapsulation layer disposed on the cathode electrode;
a first organic encapsulation layer disposed on the first inorganic encapsulation layer;
a second inorganic encapsulation layer disposed on the first organic encapsulation layer;
a second organic encapsulation layer disposed on the second inorganic encapsulation layer; and
a third inorganic encapsulation layer disposed on the second organic encapsulation layer.

6. The display device of claim 5, wherein the second encapsulation layer comprises:
a first line encapsulation layer configured to adjoin each of the plurality of stretchable connection lines;
a second line encapsulation layer disposed on the first line encapsulation layer, disposed on a same layer as the light-emitting layer, and made of a same material as the light-emitting layer;
a third line encapsulation layer disposed on the second line encapsulation layer, disposed on a same layer as the cathode electrode, and made of a same material as the cathode electrode;
a fourth line encapsulation layer disposed on the third line encapsulation layer, disposed on a same layer as the first inorganic encapsulation layer, and made of a same material as the first inorganic encapsulation layer;
a fifth line encapsulation layer disposed on the fourth line encapsulation layer, disposed on a same layer as the second inorganic encapsulation layer, and made of a same material as the second inorganic encapsulation layer; and
a sixth line encapsulation layer disposed on the fifth line encapsulation layer, disposed on a same layer as the third inorganic encapsulation layer, and made of a same material as the third inorganic encapsulation layer.

7. The display device of claim 6, wherein the light-emitting layer, the cathode electrode, the first inorganic encapsulation layer, the second inorganic encapsulation layer, and the third inorganic encapsulation layer are connected to the second line encapsulation layer, the third line encapsulation layer, the fourth line encapsulation layer, the fifth line encapsulation layer, and the sixth line encapsulation layer, respectively.

8. The display device of claim 6, wherein at least some of the light-emitting layer, the cathode electrode, the first inorganic encapsulation layer, the second inorganic encapsulation layer, and the third inorganic encapsulation layer are connected to the second line encapsulation layer, the third line encapsulation layer, the fourth line encapsulation layer, the fifth line encapsulation layer, and the sixth line encapsulation layer, respectively, and
wherein at least some of the light-emitting layer, the cathode electrode, the first inorganic encapsulation layer, the second inorganic encapsulation layer, and the third inorganic encapsulation layer are separated from the second line encapsulation layer, the third line encapsulation layer, the fourth line encapsulation layer, the fifth line encapsulation layer, and the sixth line encapsulation layer, respectively.

9. The display device of claim 8, wherein the light-emitting layer, the first inorganic encapsulation layer, the second inorganic encapsulation layer, and the third inorganic encapsulation layer are connected to the second line encapsulation layer, the fourth line encapsulation layer, the fifth line encapsulation layer, and the sixth line encapsulation layer, respectively, and
wherein the cathode electrode is separated from the third line encapsulation layer.

10. The display device of claim 6, wherein the light-emitting layer, the cathode electrode, the first inorganic encapsulation layer, the second inorganic encapsulation layer, and the third inorganic encapsulation layer are separated from the second line encapsulation layer, the third line encapsulation layer, the fourth line encapsulation layer, the fifth line encapsulation layer, and the sixth line encapsulation layer, respectively.

11. The display device of claim 6, wherein the second encapsulation layer further comprises:
a seventh line encapsulation layer disposed between the fourth line encapsulation layer and the fifth line encapsulation layer, disposed on the same layer as the first organic encapsulation layer, and made of the same material as the first organic encapsulation layer; and
a eighth line encapsulation layer disposed between the fifth line encapsulation layer and the sixth line encapsulation layer, disposed on the same layer as the second organic encapsulation layer, and made of the same material as the second organic encapsulation layer.

12. The display device of claim 11, wherein the seventh line encapsulation layer and the eighth line encapsulation layer are disposed to overlap an area, in which the plurality of stretchable connection lines is disposed, and spaced apart from the first organic encapsulation layer and the second organic encapsulation layer.

13. The display device of claim 6, further comprising:
a fluorine-based residual film disposed between the anode electrode and the light-emitting layer and between the first line encapsulation layer and the second line encapsulation layer.

14. The display device of claim 5, further comprising:
a conductive layer disposed between the plurality of plate patterns and the plurality of light-emitting elements,
wherein the conductive layer extends toward an area between the plurality of plate patterns and is connected to the plurality of stretchable connection lines, and
wherein the first inorganic encapsulation layer, the second inorganic encapsulation layer, and the third inorganic encapsulation layer are disposed to cover the conductive layer.

15. The display device of claim 14, wherein the stretchable lower substrate comprises:
a first lower substrate made of polyimide;
a second lower substrate disposed on the first lower substrate and made of an inorganic material; and
a third lower substrate disposed on the second lower substrate and made of polyimide,
wherein the plurality of stretchable connection lines is disposed between the first lower substrate and the third lower substrate, and
wherein the conductive layer is connected to the plurality of stretchable connection lines through a contact hole of the third lower substrate.
